(19) United States
(12) Patent Application Publication
(10) Pub. No.: US 2020/0209745 A1
(43) Pub. Date: Jul. 2, 2020

(54) PHOTOSENSITIVE RESIN COMPOSITION

(71) Applicant: NISSAN CHEMICAL CORPORATION, Tokyo (JP)

(72) Inventors: Takuya OHASHI, Toyama-shi (JP); Naoya NISHIMURA, Funabashi-shi (JP); Masahisa ENDO, Toyama-shi (JP); Takahiro KISHIOKA, Toyama-shi (JP)

(73) Assignee: NISSAN CHEMICAL CORPORATION, Tokyo (JP)

(21) Appl. No.: 16/643,707

(22) PCT Filed: Aug. 29, 2018
(86) PCT No.: PCT/JP2018/031879

§ 371 Date: Mar. 2, 2020

(30) Foreign Application Priority Data
Sep. 1, 2017 (JP) 2017-168785
Apr. 17, 2018 (JP) 2018-078894

(51) Int. Cl. G03F 7/038; G03F 7/028; C08G 73/12; G03F 7/16; G03F 7/20; G03F 7/38; G03F 7/32; G03F 7/40; H01L 21/027

(52) U.S. Cl. CPC G03F 7/0387; G03F 7/028; C08G 73/124; G03F 7/168; H01L 21/0274; G03F 7/2006; G03F 7/38; G03F 7/325; G03F 7/40; G03F 7/162

(57) ABSTRACT

A photosensitive resin composition which enables the achievement of a cured body that is further decreased in dielectric constant and dielectric loss tangent; a method for producing a cured relief pattern with use of this photosensitive resin composition; and a semiconductor device which is provided with this cured relief pattern. A negative photosensitive resin composition which contains 100 parts by mass of (A) a polyimide precursor that has a specific unit structure; and 0.1 to 20 parts by mass of (B) a radical photopolymerization initiator.

### TECHNICAL FIELD

The present invention relates to a negative photosensitive resin composition and a semiconductor device having a cured relief pattern obtained by curing the composition.

### BACKGROUND ART

Conventionally, a polyimide resin having excellent heat resistance and excellent electrical properties as well as excellent mechanical properties has been used in insulating materials for electronic parts, and a passivation film, a surface protective film, an interlayer dielectric film and others for semiconductor device. Among the polyimide resins, the polyimide resin provided in the form of a photosensitive polyimide precursor can easily form a heat-resistant relief pattern film by a thermal imidation treatment of the precursor by application, exposure, development, and curing. Such a photosensitive polyimide precursor has a feature that it can drastically reduce the steps, as compared to a conventional non-photosensitive-type polyimide resin.

Meanwhile, recently, from the viewpoint of improving the integration degree and operational function and reducing the chip size, the method for mounting a semiconductor device on a printed circuit board is changing. Instead of a conventional mounting method using a metal pin and a lead-tin eutectic solder, a method using a structure in which a polyimide film is directly in contact with a solder bump, such as BGA (ball grid array) or CSP (chip size packaging), which enables higher-density mounting, is being used. The polyimide film used in forming such a bump structure is required to have high heat resistance and high chemical resistance.

As the semiconductor device is further miniaturized, a problem of wiring delay arises. As a method for improving the wiring resistance of the semiconductor device, there has been a change from the conventional use of a gold or aluminum wiring to the use of a wiring of copper or a copper alloy having a lower resistance. Further, a method in which the insulation properties between wirings are improved to prevent the occurrence of wiring delay is also employed. In recent years, as a material having high insulation properties, a low permittivity material generally constitutes a semiconductor device, but the low permittivity material tends to be brittle and easily broken. For example, when a semiconductor chip including the low permittivity material is mounted on a substrate through a solder reflow step, there is a problem in that the low permittivity material suffers shrinkage due to a change of the temperature, so that the low permittivity material portion is broken. With respect to the method for solving this problem, Patent Literature 1 discloses a photosensitive resin composition comprising a polyimide precursor which has introduced an aliphatic group having 5 to 30 carbon atoms and having an ethylene glycol structure into a part of the side chain of the polyimide precursor, wherein the photosensitive resin composition has improved transparency, and further a cured film obtained by heat curing the composition has an improved Young's modulus.

### CITATION LIST

### Patent Literature

Patent Literature 1: JP 2013-168675 A

### SUMMARY OF INVENTION

### Technical Problem

The photosensitive resin composition comprising a polyimide precursor described in Patent Literature 1 has high transparency and, after the composition is subjected to heat curing, a cured product having a high Young's modulus can be obtained; however, the cured product of the resin composition is required to exhibit a further reduced permittivity and dielectric loss tangent when used in the above-mentioned applications.

Accordingly, a task of the present invention is to provide a photosensitive resin composition which forms a cured product having further reduced permittivity and dielectric loss tangent, a method for producing a cured relief pattern using the photosensitive resin composition, and a semiconductor device comprising the cured relief pattern.

### Solution to Problem

The present inventors have conducted extensive and intensive studies with a view toward achieving the above-mentioned task. As a result, it has been found that a photosensitive resin composition comprising a polyimide precursor, which has a specific chemical structure introduced into a part of the side chain of the polyimide precursor, can exhibit a low relative permittivity and a low dielectric loss tangent, and the present invention has been completed.

Specifically, the present invention is as follows.

[1] A negative photosensitive resin composition comprising:

100 parts by mass of (A) a polyimide precursor having a unit structure represented by the following general formula (1):

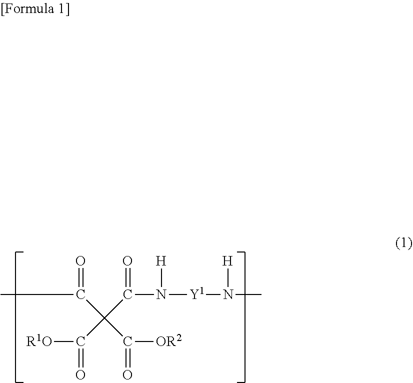

wherein X¹ is a tetravalent organic group having 6 to 40 carbon atoms, Y¹ is a divalent organic group having 6 to 40 carbon atoms, and each of R¹ and R² is independently a hydrogen atom or a monovalent organic group selected from the following general formulae (2) and (3):

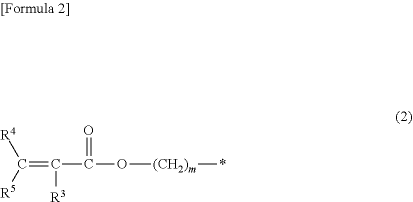

wherein each of R³, R⁴, and R⁵ is independently a hydrogen atom or a monovalent organic group having 1 to 3 carbon atoms, m is an integer of 1 to 10, and * is a site bonded to the carboxylic acid present in a polyamic acid main chain of the general formula (1),

[Formula 3]

R⁶—* (3)

wherein R⁶ is a monovalent organic group selected from alkyl groups having 1 to 30 carbon atoms, and * is as defined above, and a proportion of the total amount of the monovalent organic group represented by the general formula (2) above and the monovalent organic group represented by the general formula (3) above in the total amount of R¹ and R² is 80 mol % or more, and a proportion of the amount of the monovalent organic group represented by the general formula (3) above in the total amount of R¹ and R² is 1 to 90 mol %; and

0.1 to 20 parts by mass of (B) a radical photopolymerization initiator.

[2] The negative photosensitive resin composition according to item [1]above, wherein R⁶ is represented by the following formula (4):

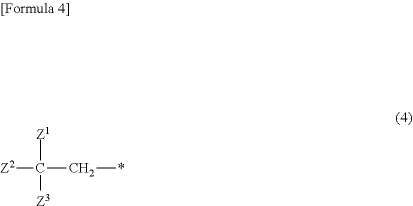

wherein Z¹ is hydrogen or an alkyl group having 1 to 14 carbon atoms,
Z² is an alkyl group having 1 to 14 carbon atoms, and
Z³ is an alkyl group having 1 to 14 carbon atoms,
wherein Z¹, Z², and Z³ may be the same or different from each other, with the proviso that the total number of carbon atoms of Z¹, Z², and Z³ is 4 or more.

[3] The negative photosensitive resin composition according to item [1] or [2] above, wherein R⁶ is selected from the following formulae (3-1) to (3-7):

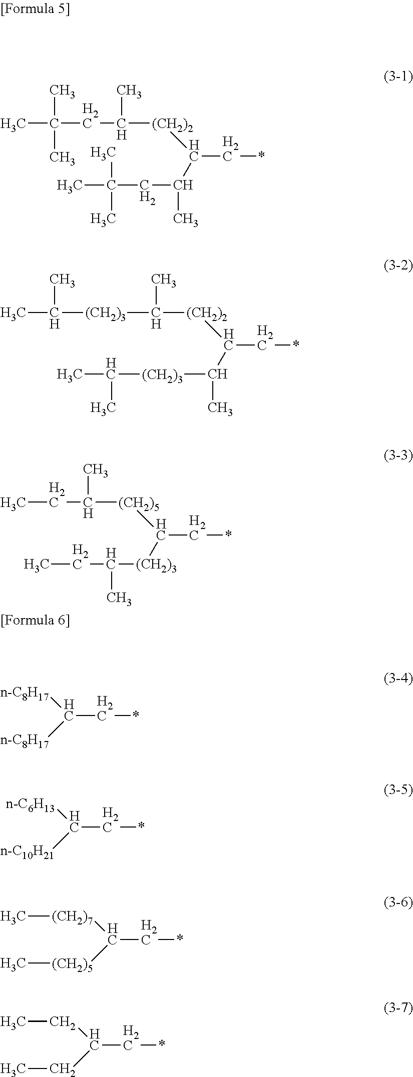

wherein * is as defined above.

[4] The negative photosensitive resin composition according to any one of items [1] to [3] above, further comprising 0.1 to 30 parts by mass of (C) a crosslinkable compound, relative to 100 parts by mass of the polyimide precursor (A).

[5] A negative photosensitive resin film which is a baked material of an applied film comprising the negative photosensitive resin composition according to any one of items [1] to [4] above.

[6] A method for producing a cured relief pattern, comprising the steps of:

(1) applying the negative photosensitive resin composition according to any one of items [1] to [4] above onto a substrate to form a photosensitive resin layer on the substrate,

(2) subjecting the photosensitive resin layer to exposure,

(3) subjecting the exposed photosensitive resin layer to development to form a relief pattern, and

(4) subjecting the relief pattern to heating treatment to form a cured relief pattern.

[7] A cured relief pattern produced by the method according to item [6] above.

[8] A semiconductor device comprising a semiconductor element, and a cured film formed on the upper portion or lower portion of the semiconductor element, wherein the cured film is the cured relief pattern according to item [6] above.

### Advantageous Effects of Invention

In the present invention, there can be provided a photosensitive resin composition which forms a cured product having a low permittivity and a low dielectric loss tangent, a method for producing a cured relief pattern using the photosensitive resin composition, and a semiconductor device comprising the cured relief pattern.

### DESCRIPTION OF EMBODIMENTS

### Negative Photosensitive Resin Composition

The negative photosensitive resin composition of the present invention comprises (A) a polyimide precursor, (B) a radical photopolymerization initiator, and, if desired, (C) a crosslinkable compound, and, if desired, other components. The components of the composition will be individually described below.

### Polyimide Precursor

In an embodiment, polyimide precursor (A) is a resin component contained in the negative photosensitive resin composition, which is a polyamide having a structure represented by the following general formula (1):

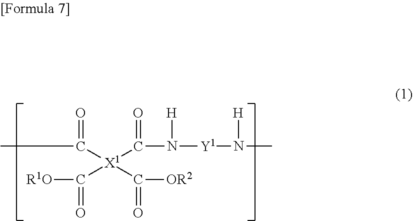

wherein X¹ is a tetravalent organic group having 6 to 40 carbon atoms, Y¹ is a divalent organic group having 6 to 40 carbon atoms, and each of R¹ and R² is independently a hydrogen atom or a monovalent organic group represented by the following general formula (2) or (3):

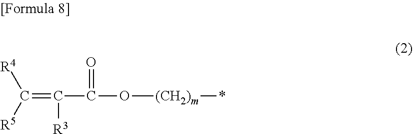

wherein each of R³, R⁴, and R⁵ is independently a hydrogen atom or a monovalent organic group having 1 to 3 carbon atoms, m is an integer of 1 to 10, and * is a site bonded to the carboxylic acid present in the polyamic acid main chain of the general formula (1),

[Formula 9]

R⁶—* (3)

wherein R⁶ is a monovalent group selected from alkyl groups having 1 to 30 carbon atoms, and * is as defined above, and a proportion of a total amount of the monovalent organic group represented by the general formula (2) above and the monovalent organic group represented by the general formula (3) above in a total amount of R¹ and R² is 80 mol % or more, and a proportion of an amount of the monovalent organic group represented by the general formula (3) above in a total amount of R¹ and R² is 1 to 90 mol %.

In the general formula (1) above, X¹ is not limited as long as it is a tetravalent organic group having 6 to 40 carbon atoms, but, from the viewpoint of achieving both excellent heat resistance and excellent photosensitivity properties, X¹ is preferably an aromatic group having a —COOR¹ group and a —COOR² group which are present in an ortho-position for a —CONH— group to each other, or an alicyclic aliphatic group. Further, the tetravalent organic group represented by X¹ is more preferably an organic group having 6 to 40 carbon atoms and containing an aromatic ring.

It is further preferred that X¹ is a tetravalent organic group represented by the following formula (5) or formulae (5-1) to (5-7).

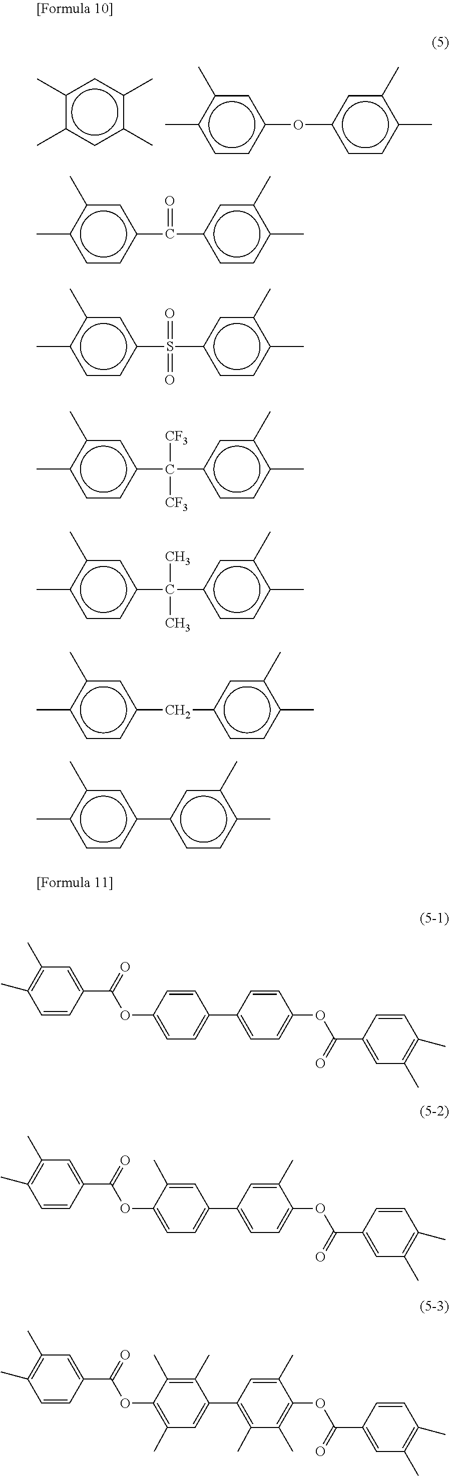

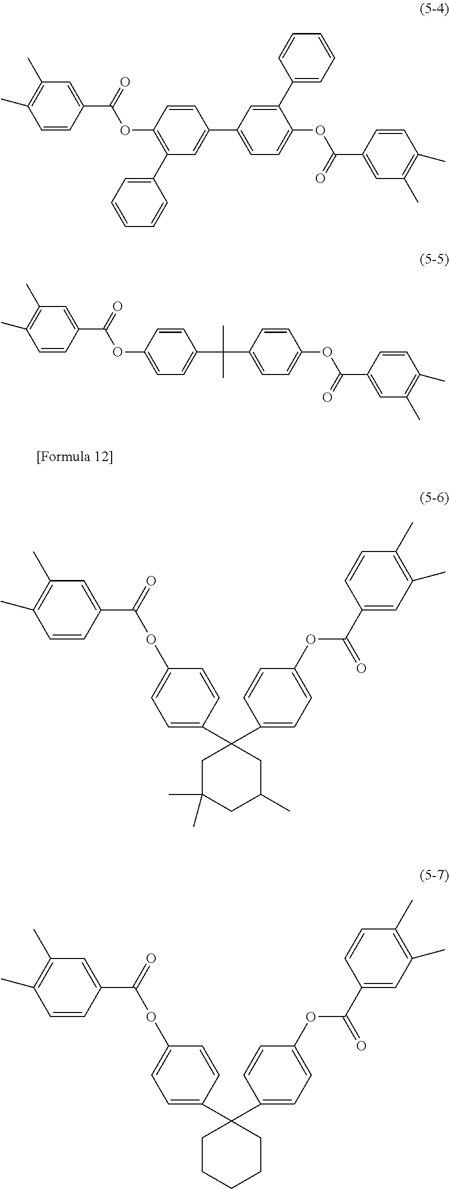

With respect to the structure of X¹, one structure or a combination of two or more structures may be employed.

In the general formula (1), Y¹ is not limited as long as it is a divalent organic group having 6 to 40 carbon atoms, but, from the viewpoint of achieving both excellent heat resistance and excellent photosensitivity properties, Y¹ is preferably a cyclic organic group having 1 to 4 aromatic rings or aliphatic rings which are optionally substituted, or an aliphatic group or siloxane group having no cyclic structure. Y¹ more preferably has a structure represented by the following general formula (6), general formula (7), or formula (8).

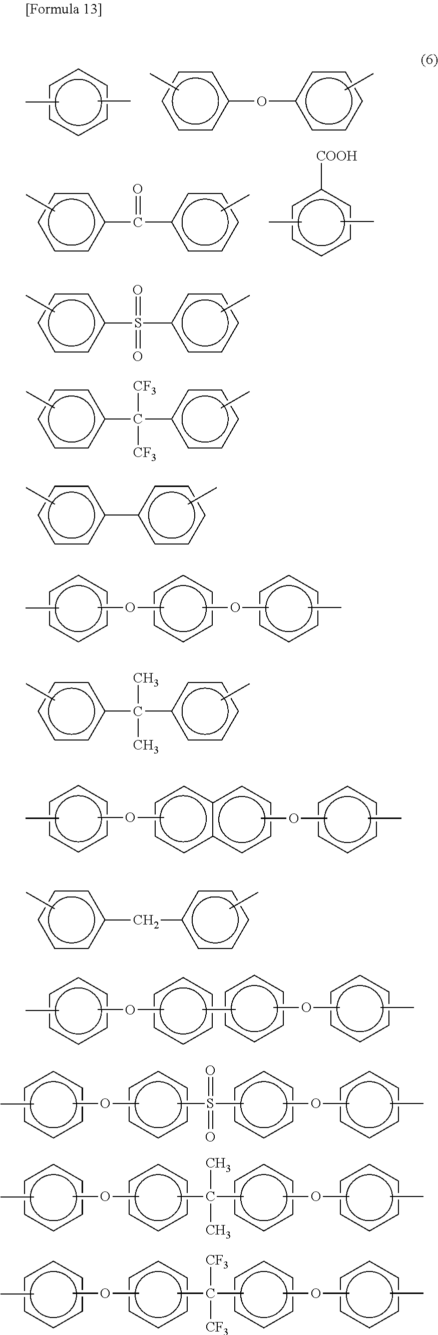

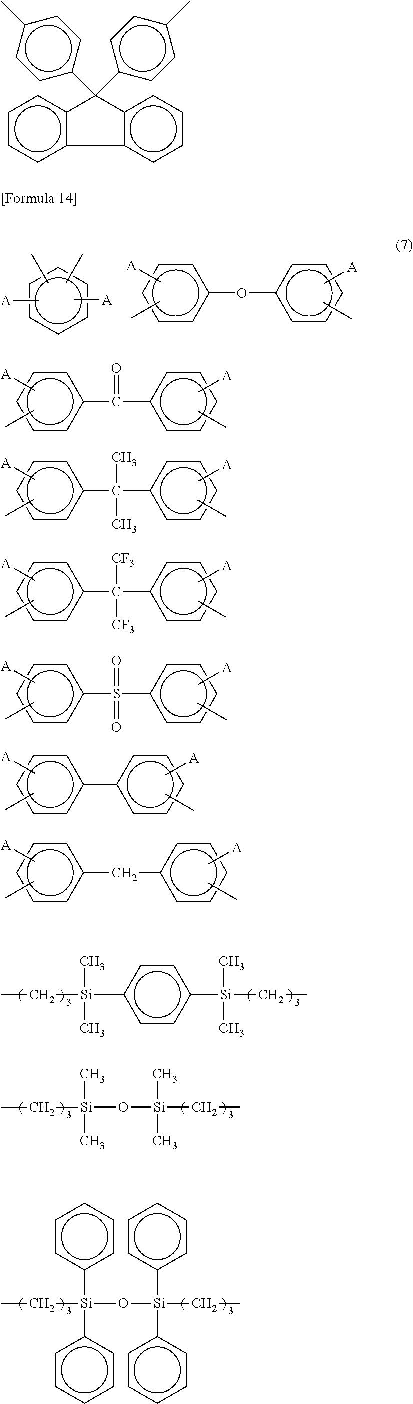

Wherein each A independently represents a methyl group (—CH₃), an ethyl group (—C₂H₅), a propyl group (—C₃H₇), or a butyl group (—C₄H₉).

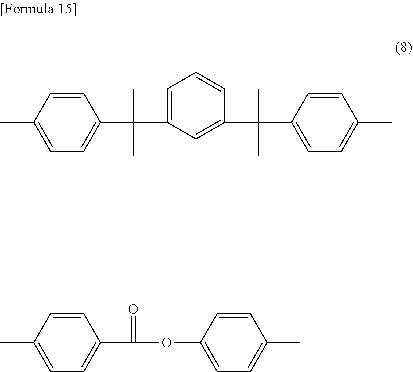

With respect to the structure of Y¹, one structure or a combination of two or more structures may be employed.

In the general formula (1), each of R¹ and R² is independently a hydrogen atom or a monovalent organic group represented by the general formula (2) or (3) above.

With respect to each of R¹ and R², one group or a combination of two or more groups may be employed, but preferred is a combination of three groups or less, preferred is a combination of two groups, and most preferred is one group.

In the general formula (1), from the viewpoint of the photosensitivity properties and mechanical properties of the photosensitive resin composition, the proportion of the total amount of the monovalent organic group represented by the general formula (2) above and the monovalent organic group represented by the general formula (3) above in the total amount of R¹ and R² is 80 mol % or more, and the proportion of the amount of the monovalent organic group represented by the general formula (3) above in the total amount of R¹ and R² ranges 1 to 90 mol %, and ranges preferably 1 to 80 mol %, preferably 1 to 70 mol %, preferably 1 to 60 mol %, preferably 1 to 50 mol %, preferably 1 to 40 mol %, preferably 1 to 30 mol %, preferably 1 to 19 mol %.

In the general formula (2) above, R³ is not limited as long as it is a hydrogen atom or a monovalent organic group having 1 to 3 carbon atoms, but, from the viewpoint of the photosensitivity properties of the photosensitive resin composition, R³ is preferably a hydrogen atom or a methyl group.

In the general formula (2), R⁴ and R⁵ are not limited as long as each of R⁴ and R⁵ is independently a hydrogen atom or a monovalent organic group having 1 to 3 carbon atoms, but, from the viewpoint of the photosensitivity properties of the photosensitive resin composition, R⁴ and R⁵ are preferably a hydrogen atom.

In the general formula (2), m is an integer of 1 to 10, and is preferably an integer of 2 to 4 from the viewpoint of the photosensitivity properties.

In the general formula (3) above, R⁶ is not limited as long as it is a monovalent organic group selected from alkyl groups having 1 to 30 carbon atoms. R⁶ may have any of a linear structure, a branched structure, and a cyclic structure.

Specific examples of the monovalent organic groups include linear alkyl groups, such as a methyl group, an ethyl group, a propyl group, a butyl group, a pentyl group (amyl group), a hexyl group, a heptyl group, an octyl group, a nonyl group, a decyl group, an undecyl group, a dodecyl group (lauryl group), a tridecyl group, a tetradecyl group (myristyl group), a pentadecyl group, a hexadecyl group (palmityl group), a heptadecyl group (margaryl group), an octadecyl group (stearyl group), a nonadecyl group, an icosyl group (arachyl group), a henicosyl group, a docosyl group (behenyl group), a tricosyl group, a tetracosyl group (lignoceryl group), a pentacosyl group, a hexacosyl group, and a heptacosyl group; branched alkyl groups, such as an isopropyl group, an isobutyl group, a sec-butyl group, a tert-butyl group, an isopentyl group, a neopentyl group, a tert-pentyl group, a sec-isoamyl group, an isohexyl group, a neohexyl group, a 4-methylhexyl group, a 5-methylhexyl group, a 1-ethylhexyl group, a 2-ethylhexyl group, a 3-ethylhexyl group, a 4-ethylhexyl group, a 2-ethylpentyl group, a heptan-3-yl group, a heptan-4-yl group, a 4-methylhexan-2-yl group, a 3-methylhexan-3-yl group, a 2,3-dimethylpentan-2-yl group, a 2,4-dimethylpentan-2-yl group, a 4,4-dimethylpentan-2-yl group, a 6-methylheptyl group, a 2-ethylhexyl group, an octan-2-yl group, a 6-methylheptan-2-yl group, a 6-methyloctyl group, a 3,5,5-trimethylhexyl group, a nonan-4-yl group, a 2,6-dimethylheptan-3-yl group, a 3,6-dimethylheptan-3-yl group, a 3-ethylheptan-3-yl group, a 3,7-dimethyloctyl group, a 8-methylnonyl group, a 3-methylnonan-3-yl group, a 4-ethyloctan-4-yl group, a 9-methyldecyl group, an undecan-5-yl group, a 3-ethylnonan-3-yl group, a 5-ethylnonan-5-yl group, a 2,2,4,5,5-pentamethylhexan-4-yl group, a 10-methylundecyl group, a 11-methyldodecyl group, a tridecan-6-yl group, a tridecan-7-yl group, a 7-ethylundecan-2-yl group, a 3-ethylundecan-3-yl group, a 5-ethylundecan-5-yl group, a 12-methyltridecyl group, a 13-methyltetradecyl group, a pentadecan-7-yl group, a pentadecan-8-yl group, a 14-methylpentadecyl group, a 15-methylhexadecyl group, a heptadecan-8-yl group, a heptadecan-9-yl group, a 3,13-dimethylpentadecan-7-yl group, a 2,2,4,8,10,10-hexamethylundecan-5-yl group, a 16-methylheptadecyl group, a 17-methyloctadecyl group, a nonadecan-9-yl group, a nonadecan-10-yl group, a 2,6,10,14-tetramethylpentadecan-7-yl group, a 18-methylnonadecyl group, a 19-methylicosyl group, a henicosan-10-yl group, a 20-methylhenicosyl group, a 21-methyldocosyl group, a tricosan-11-yl group, a 22-methyltricosyl group, a 23-methyltetracosyl group, a pentacosan-12-yl group, a pentacosan-13-yl group, a 2,22-dimethyltricosan-11-yl group, a 3,21-dimethyltricosan-11-yl group, a 9,15-dimethyltricosan-11-yl group, a 24-methylpentacosyl group, a 25-methylhexacosyl group, and a heptacosan-13-yl group; and alicyclic alkyl groups, such as a cyclopropyl group, a cyclobutyl group, a cyclopentyl group, a cyclohexyl group, a 4-tert-butylcyclohexyl group, a 1,6-dimethylcyclohexyl group, a menthyl group, a cycloheptyl group, a cyclooctyl group, a bicyclo[2.2.1]heptan-2-yl group, a bornyl group, an isobornyl group, a 1-adamantyl group, a 2-adamantyl group, a tricyclo[5.2.1.0^{2,6}]decan-4-yl group, a tricyclo[5.2.1.0^{2,6}]decan-8-yl group, and a cyclododecyl group.

In the general formula (3) above, R⁶ is preferably an alkyl group having 5 to 30 carbon atoms, preferably an alkyl group having 8 to 30 carbon atoms, preferably an alkyl group having 9 to 30 carbon atoms, preferably an alkyl group having 10 to 30 carbon atoms, further preferably an alkyl group having 11 to 30 carbon atoms, further preferably an alkyl group having 17 to 30 carbon atoms.

It is preferred that R⁶ is represented by the following formula (4):

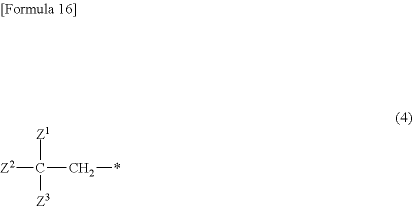

wherein Z¹ is hydrogen or an alkyl group having 1 to 14 carbon atoms,

Z² is an alkyl group having 1 to 14 carbon atoms, and
Z³ is an alkyl group having 1 to 14 carbon atoms,
wherein Z¹, Z², and Z³ may be the same or different from each other, with the proviso that the total number of carbon atoms of Z¹, Z², and Z³ is 4 or more.

Z¹ is preferably hydrogen.

Z¹, Z², and Z³ are preferably an alkyl group having 2 to 12 carbon atoms, preferably an alkyl group having 2 to 10 carbon atoms.

The total number of carbon atoms of Z¹, Z², and Z³ is preferably 5 or more, preferably 6 or more, preferably 10 or more, preferably 12 or more, preferably 14 or more, preferably 15 or more, preferably 16 or more.

The total number of carbon atoms of Z¹, Z², and Z³ is preferably 6 to 20.

The upper limit of the total number of carbon atoms of Z¹, Z², and Z³ is preferably 28.

Further, R⁶ may be selected from the following formulae (3-1) to (3-7).

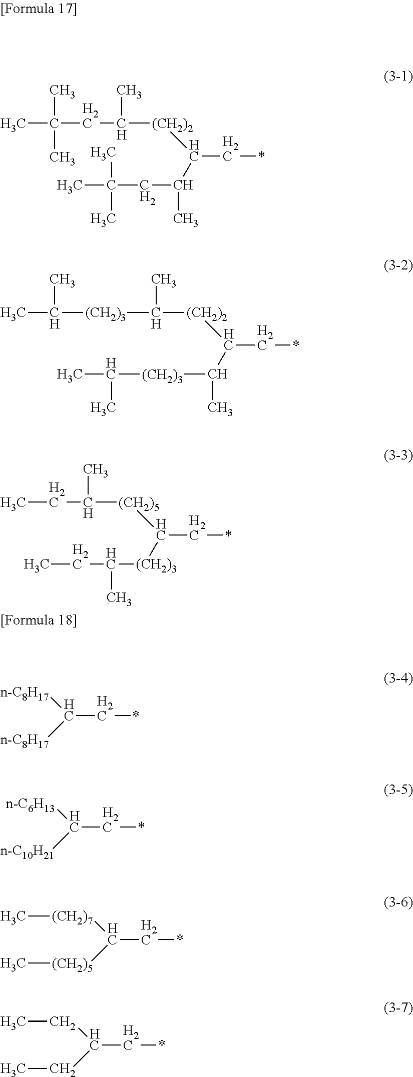

It is preferred that R⁶ is selected from the formulae (3-1) to (3-7) above.

Polyimide precursor (A) is converted to a polyimide by subjecting it to heat cyclization treatment.

### Method for Preparing Polyimide Precursor (A)

The polyimide precursor represented by the general formula (1) above in the present embodiment is obtained by, for example, reacting a tetracarboxylic dianhydride containing the above-mentioned tetravalent organic group X¹ having 6 to 40 carbon atoms, (a) an alcohol having a hydroxyl group bonded to a monovalent organic group represented by the general formula (2) above, and (b) an alcohol having a hydroxyl group bonded to a monovalent organic group represented by the general formula (3) above with each other to prepare a partially esterified tetracarboxylic acid (hereinafter, frequently referred to as “acid/ester compound”), and subsequently subjecting the acid/ester compound and a diamine containing the above-mentioned divalent organic group Y¹ having 6 to 40 carbon atoms to polycondensation.

### Preparation of an Acid/Ester Compound

In the present embodiment, examples of the tetracarboxylic dianhydrides containing a tetravalent organic group X¹ having 6 to 40 carbon atoms include pyromellitic anhydride, diphenyl ether 3,3′,4,4′-tetracarboxylic dianhydride (=4,4′-oxydiphthalic dianhydride), benzophenone-3,3′,4,4′-tetracarboxylic dianhydride, biphenyl-3,3′,4,4′-tetracarboxylic dianhydride, diphenyl sulfone 3,3′,4,4′-tetracarboxylic dianhydride, diphenylmethane-3,3′,4,4′-tetracarboxylic dianhydride, 2,2-bis(3,4-phthalic anhydride)propane, and 2,2-bis(3,4-phthalic anhydride)-1,1,1,3,3,3-hexafluoropropane.

Further, examples include tetracarboxylic dianhydrides represented by the following formulae (5-1-a) to (5-7-a).

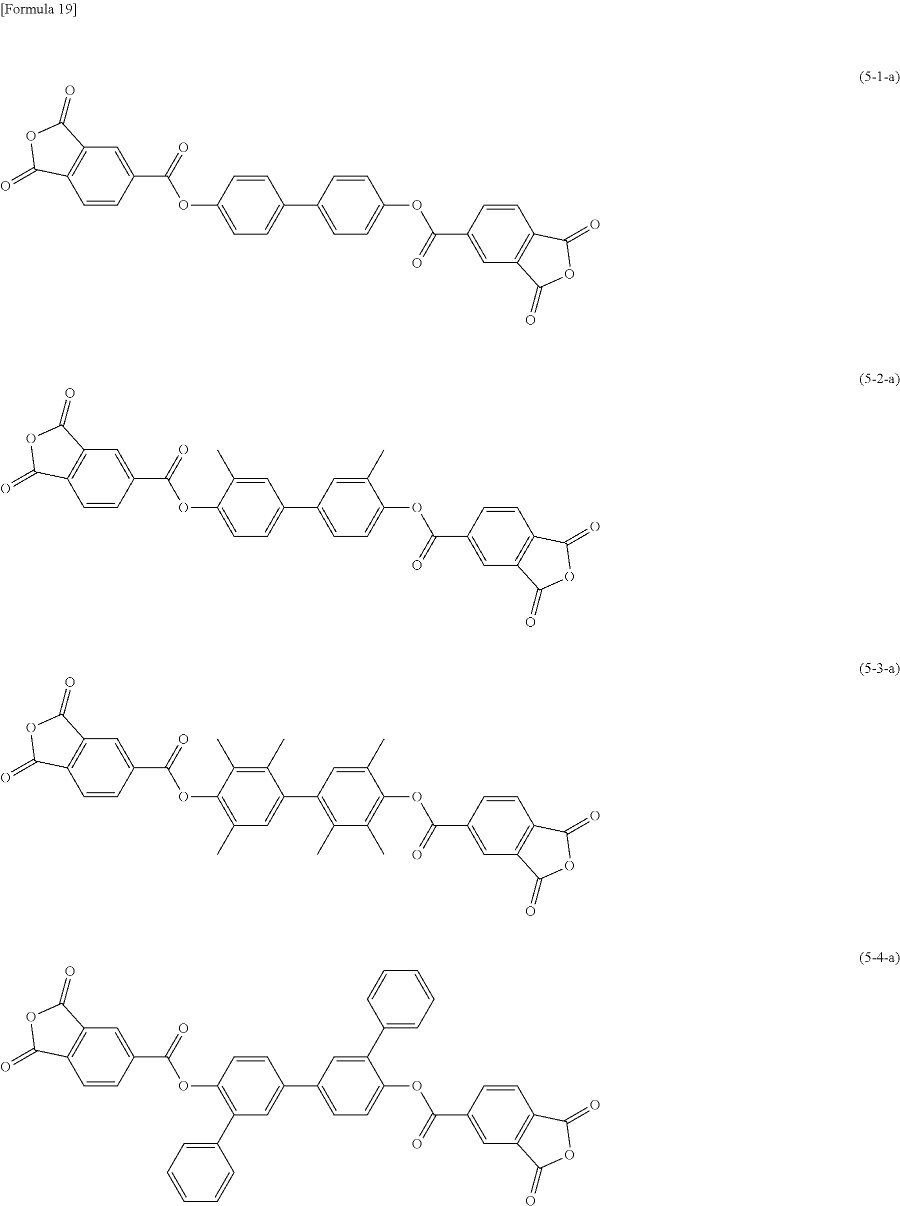 [SMILES: O=C(Oc1ccc(-c2ccc(OC(=O)c3ccc4c(c3)C(=O)OC4=O)cc2)cc1)c1ccc2c(c1)C(=O)OC2=O ; Cc1cc(-c2ccc(OC(=O)c3ccc4c(c3)C(=O)OC4=O)c(C)c2)ccc1OC(=O)c1ccc2c(c1)C(=O)OC2=O ; Cc1cc(-c2cc(C)c(OC(=O)c3ccc4c(c3)C(=O)OC4=O)c(C)c2C)c(C)c(C)c1OC(=O)c1ccc2c(c1)C(=O)OC2=O ; O=C(Oc1ccc(-c2ccc(OC(=O)c3ccc4c(c3)C(=O)OC4=O)c(-c3ccccc3)c2)cc1-c1ccccc1)c1ccc2c(c1)C(=O)OC2=O]

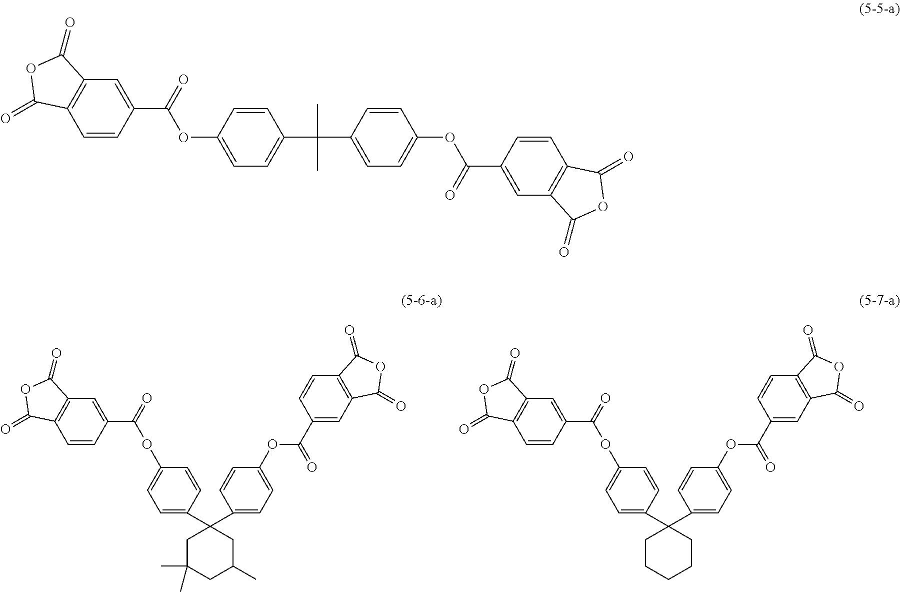 [SMILES: CC(C)(c1ccc(OC(=O)c2ccc3c(c2)C(=O)OC3=O)cc1)c1ccc(OC(=O)c2ccc3c(c2)C(=O)OC3=O)cc1 ; CC1CC(C)(C)CC(c2ccc(OC(=O)c3ccc4c(c3)C(=O)OC4=O)cc2)(c2ccc(OC(=O)c3ccc4c(c3)C(=O)OC4=O)cc2)C1 ; O=C(Oc1ccc(C2(c3ccc(OC(=O)c4ccc5c(c4)C(=O)OC5=O)cc3)CCCCC2)cc1)c1ccc2c(c1)C(=O)OC2=O]

These can be used individually or in combination.

In the present embodiment, examples of alcohols (a) having a structure represented by the general formula (2) above include 2-acryloyloxyethyl alcohol, 1-acryloyloxy-3-propyl alcohol, methylol vinyl ketone, 2-hydroxyethyl vinyl ketone, 2-hydroxy-3-methoxypropyl acrylate, 2-hydroxy-3-butoxypropyl acrylate, 2-hydroxy-3-butoxypropyl acrylate, 2-methacryloyloxyethyl alcohol, 1-methacryloyloxy-3-propyl alcohol, 2-hydroxy-3-methoxypropyl methacrylate, 2-hydroxy-3-butoxypropyl methacrylate, 2-hydroxy-3-butoxypropyl methacrylate, and 2-hydroxyethyl methacrylate.

Examples of aliphatic alcohols (b) having 1 to 30 carbon atoms and being represented by the general formula (3) above include alcohols obtained by replacing a hydrogen atom of the above-mentioned alkyl group having 1 to 30 carbon atoms by a hydroxyl group.

Further, alcohols having structures of the formulae (3-1) to (3-6) above may be used.

The following commercially available products may be used:

an alcohol having a structure of the formula (3-1): FINEOXOCOL® 180 (manufactured by Nissan Chemical Industries, Ltd.),

an alcohol having a structure of the formula (3-2): FINEOXOCOL® 2000 (manufactured by Nissan Chemical Industries, Ltd.),

an alcohol having a structure of the formula (3-3): FINEOXOCOL® 180N (manufactured by Nissan Chemical Industries, Ltd.),

an alcohol having a structure of the formula (3-4) or (3-5): FINEOXOCOL® 180T (manufactured by Nissan Chemical Industries, Ltd.), and

an alcohol having a structure of the formula (3-6): FINEOXOCOL® 1600K (manufactured by Nissan Chemical Industries, Ltd.).

With respect to the above alcohols, it is preferred that alcohols having structures of the formulae (3-1) to (3-6) above are used.

In the negative photosensitive resin composition, the content of the total of the above-mentioned component (a) and component (b) in the total of le and R² in the general formula (1) is preferably 80 mol % or more, and, for achieving a low permittivity and a low dielectric loss tangent, the content of component (b) in the total of R¹ and R² ranges preferably 1 to 90 mol %.

The above-mentioned tetracarboxylic dianhydride and the above-mentioned alcohols are stirred, dissolved, and mixed in the presence of a basic catalyst, such as pyridine, in a reaction solvent at a reaction temperature of 0 to 100° C. for 10 to 40 hours to cause a half-esterification reaction of the acid dianhydride to proceed, obtaining a desired acid/ester compound.

With respect to the reaction solvent, preferred is a solvent capable of dissolving therein the acid/ester compound and the polyimide precursor which is a polycondensation product of the acid/ester compound and the diamine, and examples of such solvents include N-methyl-2-pyrrolidone, N,N-dimethylacetamide, N,N-dimethylformamide, dimethyl sulfoxide, tetramethylurea, gamma-butyrolactone, ketones, esters, lactones, ethers, halogenated hydrocarbons, hydrocarbons, acetone, methyl ethyl ketone, methyl isobutyl ketone, cyclohexanone, methyl acetate, ethyl acetate, butyl acetate, diethyl oxalate, ethylene glycol dimethyl ether, diethylene glycol dimethyl ether, tetrahydrofuran, dichloromethane, 1,2-dichloroethane, 1,4-dichlorobutane, chlorobenzene, o-dichlorobenzene, hexane, heptane, benzene, toluene, and xylene. These may be used individually or in combination if necessary.

### Preparation of a Polyimide Precursor

A known dehydration condensing agent, for example, dicyclohexylcarbodiimide, 1-ethoxycarbonyl-2-ethoxy-1,2-dihydroquinoline, 1,1-carbonyldioxy-di-1,2,3-benzotriazole, or N,N′-disuccinimidyl carbonate is added to and mixed into the above-mentioned acid/ester compound (which is typically in the form of a solution in the reaction solvent) while cooling in an ice bath to change the acid/ester compound to a polyacid anhydride, and then a solution or dispersion separately prepared by dissolving or dispersing a diamine containing divalent organic group Y¹ having 6 to 40 carbon atoms in a solvent is dropwise added to the resultant reaction mixture to cause polycondensation, obtaining a polyimide precursor which can be used in the embodiment.

Examples of the diamines containing a divalent organic group Y¹ having 6 to 40 carbon atoms include p-phenylenediamine, m-phenylenediamine, 4,4-diaminodiphenyl ether, 3,4′-diaminodiphenyl ether, 3,3′-diaminodiphenyl ether, 4,4′-diaminodiphenyl sulfide, 3,4′-diaminodiphenyl sulfide, 3,3′-diaminodiphenyl sulfide, 4,4′-diaminodiphenyl sulfone, 3,4′-diaminodiphenyl sulfone, 3,3′-diaminodiphenyl sulfone, 4,4′-diaminobiphenyl, 3,4′-diaminobiphenyl, 3,3′-diaminobiphenyl, 4,4′-diaminobenzophenone, 3,4′-diaminobenzophenone, 3,3′-diaminobenzophenone, 4,4′-diaminodiphenylmethane, 3,4′-diaminodiphenylmethane, 3,3′-diaminodiphenylmethane, 1,4-bis(4-aminophenoxy)benzene, 1,3-bis(4-aminophenoxy)benzene, 1,3-bis(3-aminophenoxy)benzene, bis[4-(4-aminophenoxy)phenyl] sulfone, bis[4-(3-aminophenoxy)phenyl] sulfone, 4,4′-bis(4-aminophenoxy)biphenyl, 4,4-bis(3-aminophenoxy)biphenyl, bis[4-(4-aminophenoxy)phenyl] ether, bis[4-(3-aminophenoxy)phenyl] ether, 1,4-bis(4-aminophenyl)benzene, 1,3-bis(4-aminophenyl)benzene, 9,10-bis(4-aminophenyl)anthracene, 2,2-bis(4-aminophenyl)propane, 2,2-bis(4-aminophenyl)hexafluoropropane, 2,2-bis[4-(4-aminophenoxy)phenyl]propane, 2,2-bis[4-(4-aminophenoxy)phenyl]hexafluoropropane, 1,4-bis(3-aminopropyldimethylsilyl)benzene, ortho-tolidine sulfone, 9,9-bis(4-aminophenyl)fluorene, and these diamines having part of hydrogen atoms on their benzene ring replaced by, e.g., a methyl group, an ethyl group, a hydroxymethyl group, a hydroxyethyl group, or a halogen, such as 3,3′-dimethyl-4,4′-diaminobiphenyl, 2,2′-dimethyl-4,4′-diaminobiphenyl, 3,3′-dimethyl-4,4′-diaminodiphenylmethane, 2,2′-dimethyl-4,4′-diaminodiphenylmethane, 3,3′-dimethoxy-4,4′-diaminobiphenyl, and 3,3′-dichloro-4,4′-diaminobiphenyl, and mixtures thereof.

Further, examples include diamines represented by the following formula (8-1).

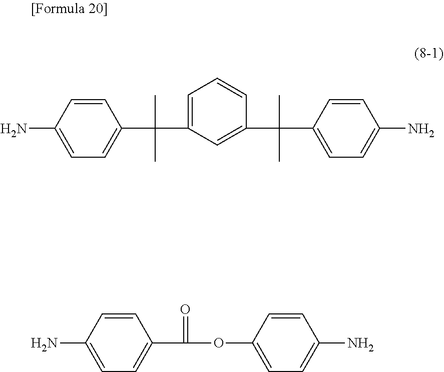 [SMILES: CC(C)(c1ccc(N)cc1)c1cccc(C(C)(C)c2ccc(N)cc2)c1 ; Nc1ccc(OC(=O)c2ccc(N)cc2)cc1]

The diamine used in the present invention is not limited to these diamines.

In the embodiment, for improving the adhesion between a photosensitive resin layer formed on a substrate by applying the negative photosensitive resin composition onto a substrate and a various types of substrates, a diaminosiloxane, such as 1,3-bis(3-aminopropyl)tetramethyldisiloxane or 1,3-bis(3-aminopropyl)tetraphenyldisiloxane, can be copolymerized with polyimide precursor (A) during the preparation of the polyimide precursor.

After completion of the polycondensation reaction, the water absorbing by-product of the dehydration condensing agent present in the reaction solution is removed by filtration if necessary, and then a poor solvent, such as water, an aliphatic lower alcohol, or a mixture thereof, is poured into the reaction solution to cause precipitation of the polymer component, and further the resultant polymer is purified by repeating re-dissolution and reprecipitation operations of the polymer, and subjected to vacuum drying to isolate a polyimide precursor which can be used in the embodiment. For improving the purification degree, a solution of the polymer may be passed through a column packed with an anion and/or cation exchange resin swelled with an appropriate organic solvent to remove ionic impurities.

Polyimide precursor (A) preferably has a molecular weight of 5,000 to 150,000, more preferably 7,000 to 50,000, in terms of a weight average molecular weight, as measured by gel permeation chromatography using a conversion calibratiocurve obtained from polystyrene. When the weight average molecular weight of polyimide precursor (A) is 5,000 or more, excellent mechanical properties advantageously can be obtained. On the other hand, when the weight average molecular weight of polyimide precursor (A) is 150,000 or less, excellent dispersibility into a developer and excellent resolution performance of a relief pattern advantageously can be obtained.

### (B) Radical Photopolymerization Initiator

The negative photosensitive resin composition of the present invention comprises a radical photopolymerization initiator as component (B). With respect to the radical photopolymerization initiator, there is no particular limitation as long as it is a compound having an absorption for the light source used in photo-curing, but examples of radical photopolymerization initiators include organic peroxides, such as tert-butyl peroxy-iso-butyrate, 2,5-dimethyl-2,5-bis(benzoyldioxy)hexane, 1,4-bis[a-(tert-butyldioxy)-iso-propoxy]benzene, di-tert-butyl peroxide, 2,5-dimethyl-2,5-bis(tert-butyldioxy)hexene hydroperoxide, α-(iso-propylphenyl)-iso-propyl hydroperoxide, tert-butyl hydroperoxide, 1,1-bis(tert-butyldioxy)-3,3,5-trimethylcyclohexane, butyl 4,4-bis(tert-butyldioxy)valerate, cyclohexanone peroxide, 2,2′,5,5′-tetra(tert-butylperoxycarbonyl)benzophenone, 3,3′,4,4′-tetra(tert-butylperoxycarbonyl)benzophenone, 3,3′,4,4′-tetra(tert-amylperoxycarbonyl)benzophenone, 3,3′,4,4′-tetra(tert-hexylperoxycarbonyl)benzophenone, 3,3′ -bis(tert-butylperoxycarbonyl)-4,4′-dicarboxybenzophenone, tert-butyl peroxybenzoate, and di-tert-butyl diperoxyisophthalate; quinones, such as 9,10-anthraquinone, 1-chloroanthraquinone, 2-chloroanthraquinone, octamethylanthraquinone, and 1,2-benzanthraquinone; benzoin derivatives, such as benzoin methyl, benzoin ethyl ether, a-methylbenzoin, and α-phenylbenzoin; alkylphenone compounds, such as 2,2-dimethoxy-1,2-diphenylethan-1-one, 1-hydroxy-cyclohexyl phenyl ketone, 2-hydroxy-2-methyl-1-phenyl-propan-1-one, 1-[4-(2-hydroxyethoxy)-phenyl]-2-hydroxy-2-methyl-1-propan-1-one, 2-hydroxy-1-[4-{4-(2-hydroxy-2-methyl-propionyl)benzyl}-phenyl]-2-methyl-propan-1-one, phenylglyoxylic acid methyl ester, 2-methyl-1-[4-(methylthio)phenyl]-2-morpholinopropan-1-one, 2-benzyl-2-dimethylamino-1-(4-morpholinophenyl)-1-butanone, and 2-dimethylamino-2-(4-methyl-benzyl)-1-(4-morpholin-4-yl-phenyl)-butan-l-one; acylphosphine oxide compounds, such as bis(2,4,6-trimethylbenzoyl)-phenylphosphine oxide and 2,4,6-trimethylbenzoyl-diphenyl-phosphine oxide; and oxime ester compounds, such as 2-(O-benzoyloxime)-1-[4-(phenylthio)phenyl]-1,2-octanedione and 1-(O-acetyloxime)-1-[9-ethyl-6-(2-methylbenzoyl)-9H-carbazol-3-yl]ethanone.

The radical photopolymerization initiator is commercially available, and examples of commercially available products include IRGACURE® 651, IRGACURE® 184, IRGACURE® 2959, IRGACURE® 127, IRGACURE® 907, IRGACURE® 369, IRGACURE® 379EG, IRGACURE® 819, IRGACURE® 819DW, IRGACURE® 1800, IRGACURE® 1870, IRGACURE® 784, IRGACURE® OXE01, IRGACURE® OXE02, IRGACURE® 250, IRGACURE® 1173, IRGACURE® MBF, IRGACURE® TPO, IRGACURE® 4265, IRGACURE® TPO (each of which is manufactured by BASF AG), KAYACURE® DETX, KAYACURE® MBP, KAYACURE® DMBI, KAYACURE® EPA, KAYACURE® OA (each of which is manufactured by Nippon Kayaku Co., Ltd.), VICURE-10, VICURE-55 (each of which is manufactured by STAUFFER Co., LTD.), ESACURE KIP150, ESACURE TZT, ESACURE 1001, ESACURE KT046, ESACURE KB1, ESACURE KL200, ESACURE KS300, ESACURE EB3, Triazine-PMS, Triazine A, Triazine B (each of which is manufactured by Nihon Siber Hegner K.K.), and Adeka Optomer N-1717, Adeka Optomer N-1414, Adeka Optomer N-1606 (each of which is manufactured by ADEKA Corporation). These radical photopolymerization initiators may be used individually or in combination.

The amount of the radical photopolymerization initiator (B) incorporated, relative to 100 parts by mass of polyimide precursor (A), is 0.1 to 20 parts by mass, and ranges preferably 0.5 to 15 parts by mass from the viewpoint of the photosensitivity properties. When radical photopolymerization initiator (B) is incorporated in an amount of 0.1 part by mass or more, relative to 100 parts by mass of polyimide precursor (A), the obtained negative photosensitive resin composition has excellent photosensitivity. On the other hand, when radical photopolymerization initiator (B) is incorporated in an amount of 20 parts by mass or less, the obtained negative photosensitive resin composition exhibits excellent curing properties for a film having an increased thickness.

### (C) Crosslinkable Compound

In the embodiment, it is preferred that the negative photosensitive resin composition further comprises (C) a crosslinkable compound. The crosslinkable compound can serve as a crosslinking agent such that, when a relief pattern formed using the negative photosensitive resin composition is photo-cured, the crosslinkable compound can cause polyimide precursor (A) to be crosslinked or the crosslinkable compound itself can form a crosslinked network. Crosslinkable compound (C) advantageously can further improve the heat resistance and chemical resistance of a cured film formed from the negative photosensitive resin composition. Examples of light sources used in the exposure for the film include a g-line, an h-line, an i-line, a ghi-line broad band, and a KrF excimer laser. The exposed dose is desirably 25 to 1,000 mJ/cm².

In the embodiment, for improving the resolution of the relief pattern, a monomer having a photopolymerizable unsaturated bond can be optionally incorporated into the negative photosensitive resin composition. As such a monomer, preferred is (a)an (meth)acrylic compound which undergoes a radical polymerization reaction due to a photopolymerization initiator, and there is no particular limitation, but examples of monomers include ethylene glycol or polyethylene glycol mono- or di-acrylate or methacrylate, such as diethylene glycol dimethacrylate and tetraethylene glycol dimethacrylate, propylene glycol or polypropylene glycol mono- or di-acrylate or methacrylate, glycerol mono-, di-, or tri-acrylate or methacrylate, cyclohexane diacrylate or dimethacrylate, 1,4-butanediol diacrylate or dimethacrylate, 1,6-hexanediol diacrylate or dimethacrylate, neopentyl glycol diacrylate or dimethacrylate, bisphenol A mono- or di-acrylate or methacrylate, benzene trimethacrylate, isobornyl acrylate or methacrylate, acrylamide and derivatives thereof, methacrylamide and derivatives thereof, trimethylolpropane triacrylate or methacrylate, glycerol di- or tri-acrylate or methacrylate, pentaerythritol di-, tri-, or tetra-acrylate or methacrylate, and compounds, such as ethylene oxide or propylene oxide addition products of the above compounds.

The amount of the incorporated monomer having a photopolymerizable unsaturated bond ranges preferably 1 to 50 parts by mass, relative to 100 parts by mass of polyimide precursor (A).

For example, there can be mentioned a bifunctional (meth)acrylate. The bifunctional (meth)acrylate means a compound having an acryloyl group or a methacryloyl group at both ends of the molecule thereof. Examples of such compounds include tricyclodecanedimethanol diacrylate, tricyclodecanedimethanol dimethacrylate, tricyclodecanediethanol diacrylate, and tricyclodecanediethanol dimethacrylate.

The bifunctional (meth)acrylate is commercially available, and examples of commercially available products include A-DCP, DCP (each of which is manufactured by Shin-Nakamura Chemical Co., Ltd.), and NEW FRONTIER® HBPE-4 (manufactured by Dai-ich Kogyo Seiyaku Co., Ltd.). These compounds may be used individually or in combination.

The amount of crosslinkable compound (C) contained in the negative photosensitive resin composition of the present invention is not limited as long as the amount of crosslinkable compound (C) is 0.1 to 50 parts by mass, relative to 100 parts by mass of polyimide precursor (A). Especially, the amount of crosslinkable compound (C) ranges preferably 0.5 to 30 parts by mass. When the amount of crosslinkable compound (C) is 0.1 part by mass or more, the obtained resin composition exhibits excellent heat resistance and excellent chemical resistance. On the other hand, when the amount of crosslinkable compound (C) is 50 parts by mass or less, the obtained resin composition advantageously has excellent storage stability. With respect to the amount of the crosslinkable compound contained, for example, when two or more compounds are used, the total amount of the compounds is used.

### Other Components

In the embodiment, the negative photosensitive resin composition may further contain a component other than the above-mentioned components (A) to (C). Examples of other components include a solvent, a resin component other than the above-mentioned polyimide precursor (A), a sensitizer, a bonding auxiliary, a thermal polymerization inhibitor, an azole compound, a hindered phenol compound, and a filler.

Examples of thermal crosslinking agents include hexamethoxymethylmelamine, tetramethoxymethylglycoluril, tetramethoxymethylbenzoguanamine, 1,3,4,6-tetrakis(methoxymethyl)glycoluril, 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, and 1,1,3,3-tetrakis(methoxymethyl)urea.

Examples of fillers include inorganic fillers, specifically, sols, such as silica, aluminum nitride, boron nitride, zirconia, and alumina.

With respect to the solvent, in view of the dissolving power for polyimide precursor (A), an organic solvent is preferably used. Specific examples of organic solvents include N,N-dimethylformamide, N-methyl-2-pyrrolidone, N-ethyl-2-pyrrolidone, N,N-dimethylacetamide, dimethyl sulfoxide, diethylene glycol dimethyl ether, cyclopentanone, cyclohexanone, γ-butyrolactone, α-acetyl-γ-butyrolactone, tetramethylurea, 1,3-dimethyl-2-imidazolinone, and N-cyclohexyl-2-pyrrolidone, and these can be used individually or in combination.

According to a desired thickness of the applied film of the negative photosensitive resin composition and a desired viscosity of the composition, the solvent can be used in an amount, for example, in the range of from 30 to 1,500 parts by mass, preferably in the range of from 100 to 1,000 parts by mass, relative to 100 parts by mass of polyimide precursor (A).

In the embodiment, the negative photosensitive resin composition may further contain a resin component other than the above-mentioned polyimide precursor (A). Examples of resin components which can be contained in the negative photosensitive resin composition include polyimide, polyoxazole, a polyoxazole precursor, a phenolic resin, polyamide, an epoxy resin, a siloxane resin, and an acrylic resin.

The amount of the above resin component incorporated is preferably in the range of from 0.01 to 20 parts by mass, relative to 100 parts by mass of polyimide precursor (A).

In the embodiment, for improving the photosensitivity, a sensitizer can be optionally incorporated into the negative photosensitive resin composition. Examples of the sensitizers include Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobenzal)-4-methylcyclohexanone, 4,4′-bis(dimethylamino)chalcone, 4,4′-bis(diethylamino)chalcone, p-dimethylaminocinnamylideneindanone, p-dimethylaminobenzylideneindanone, 2-(p-dimethylaminophenylbiphenylene)-benzothiazole, 2-(p-dimethylaminophenylvinylene)benzothiazole, 2-(p-dimethylaminophenylvinylene)isonaphthothiazole, 1,3-bis(4′-dimethylaminobenzal)acetone, 1,3-bis(4′-diethylaminobenzal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin, N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethylaminostyryl)benzoxazole, 2-(p-dimethylaminostyryl)benzothiazole, 2-(p-dimethylaminostyryl)naphtho(1,2-d)thiazole, and 2-(p-dimethylaminobenzoyl)styrene. These can be used individually or in combination.

The amount of the sensitizer incorporated ranges preferably 0.1 to 25 parts by mass, relative to 100 parts by mass of polyimide precursor (A).

In the embodiment, for improving the adhesion between a film formed using the negative photosensitive resin composition and a substrate, a bonding auxiliary can be optionally incorporated into the negative photosensitive resin composition. Examples of bonding auxiliaries include silane coupling agents, such as γ-aminopropyldimethoxysilane, N-(β-aminoethyl)-γ-aminopropylmethyldimethoxysilane, γ-glycidoxypropylmethyldimethoxysilane, γ-mercaptopropylmethyldimethoxysilane, 3-methacryloxypropyldimethoxymethylsilane, 3-methacryloxypropyltrimethoxysilane, dimethoxymethyl-3-piperidinopropylsilane, diethoxy-3-glycidoxypropylmethylsilane, N-(3-diethoxymethylsilylpropyl)succinimide, N[3-(triethoxysilyl)propyl]phthalamic acid, benzophenone-3,3′-bis(N-[3-triethoxysilyl]propylamido)-4,4′-dicarboxylic acid, benzene-1,4-bis(N-[3-triethoxysilyl]propylamido)-2,5-dicarboxylic acid, 3-(triethoxysilyl)propylsuccinic anhydride, and N-phenylaminopropyltrimethoxysilane, and aluminum bonding auxiliaries, such as aluminum tris(ethyl acetoacetate), aluminum tris(acetylacetonate), and ethyl acetoacetate aluminum diisopropylate.

Among these bonding auxiliaries, in view of the bonding force, a silane coupling agent is more preferably used. The amount of the bonding auxiliary incorporated is preferably in the range of from 0.5 to 25 parts by mass, relative to 100 parts by mass of polyimide precursor (A).

In the embodiment, for improving the viscosity and photosensitivity stability of the negative photosensitive resin composition, especially when stored in the state of a solution containing a solvent, a thermal polymerization inhibitor can be optionally incorporated into the composition. As a thermal polymerization inhibitor, there is used, for example, hydroquinone, N-nitrosodiphenylamine, p-tert-butylcatechol, phenothiazine, N-phenylnaphthylamine, ethylenediaminetetraacetic acid, 1,2-cyclohexanediaminetetraacetic acid, glycol ether diaminetetraacetic acid, 2,6-di-tert-butyl-p-methylphenol, 5-nitroso-8-hydroxyquinoline, 1-nitroso-2-naphthol, 2-nitroso-1-naphthol, 2-nitroso-5-(N-ethyl-N-sulfopropylamino)phenol, N-nitroso-N-phenylhydroxylamine ammonium salt, or N-nitroso-N(1-naphthyl)hydroxylamine ammonium salt.

The amount of the thermal polymerization inhibitor incorporated is preferably in the range of from 0.005 to 12 parts by mass, relative to 100 parts by mass of polyimide precursor (A).

For example, when a substrate formed from copper or a copper alloy is used, for suppressing discoloration of the substrate, an azole compound can be optionally incorporated into the negative photosensitive resin composition. Examples of azole compounds include 1H-triazole, 5-methyl-1H-triazole, 5-ethyl-1H-triazole, 4,5-dimethyl-1H-triazole, 5-phenyl-1H-triazole, 4-t-butyl-5-phenyl-1H-triazole, 5-hydroxyphenyl-1H-triazole, phenyltriazole, p-ethoxyphenyltriazole, 5-phenyl-1-(2-dimethylaminoethyl)triazole, 5-benzyl-1H-triazole, hydroxyphenyltriazole, 1,5-dimethyltriazole, 4,5-diethyl-1H-triazole, 1H-benzotriazole, 2-(5-methyl-2-hydroxyphenyl)benzotriazole, 2-[2-hydroxy-3,5-bis(α,α-dimethylbenzyl)phenyl]-benzotriazole, 2-(3,5-di-t-butyl-2-hydroxyphenyl)benzotriazole, 2-(3-t-butyl-5-methyl-2-hydroxyphenyl)-benzotriazole, 2-(3,5-di-t-amyl-2-hydroxyphenyl)benzotriazole, 2-(2′-hydroxy-5′-t-octylphenyl)benzotriazole, hydroxyphenylbenzotriazole, tolyltriazole, 5-methyl-1H-benzotriazole, 4-methyl-1H-benzotriazole, 4-carboxy-1H-benzotriazole, 5-carboxy-1H-benzotriazole, 1H-tetrazole, 5-methyl-1H-tetrazole, 5-phenyl-1H-tetrazole, 5-amino-1H-tetrazole, and 1-methyl-1H-tetrazole. Especially preferred examples include tolyltriazole, 5-methyl-1H-benzotriazole, and 4-methyl-1H-benzotriazole. These azole compounds may be used individually or in combination.

The amount of the azole compound incorporated, relative to 100 parts by mass of polyimide precursor (A), ranges preferably 0.1 to 20 parts by mass, and is more preferably 0.5 to 5 parts by mass from the viewpoint of the photosensitivity properties. When the amount of the azole compound incorporated is 0.1 part by mass or more, relative to 100 parts by mass of polyimide precursor (A), the obtained negative photosensitive resin composition, which is applied onto copper or a copper alloy, suppresses discoloration of the surface of the copper or copper alloy. On the other hand, when the amount of the azole compound incorporated is 20 parts by mass or less, the obtained negative photosensitive resin composition advantageously has excellent photosensitivity.

In the embodiment, for suppressing discoloration caused on copper, a hindered phenol compound can be optionally incorporated into the negative photosensitive resin composition. Examples of hindered phenol compounds include 2,6-di-t-butyl-4-methylphenol, 2,5-di-t-butyl-hydroquinone, octadecyl 3-(3,5-di-t-butyl-4-hydroxyphenyl)propionate, isooctyl 3-(3,5-di-t-butyl-4-hydroxyphenyl)propionate, 4,4′-methylenebis(2,6-di-t-butylphenol), 4,4′-thio-bis(3-methyl-6-t-butylphenol), 4,4′-butylidene-bis(3-methyl-6-t-butylphenol), triethylene glycol bis[3-(3-t-butyl-5-methyl-4-hydroxyphenyl)propionate], 1,6-hexanediol bis[3-(3,5-di-t-butyl-4-hydroxyphenyl)propionate], 2,2-thio-diethylene bis[3-(3,5-di-t-butyl-4-hydroxyphenyl)propionate], N,N′-hexamethylenebis(3,5-di-t-butyl-4-hydroxy-hydrocinnamamide), 2,2′-methylene-bis(4-methyl-6-t-butylphenol), 2,2′-methylene-bis(4-ethyl-6-t-butylphenol), pentaerythrityl tetrakis[3-(3,5-di-t-butyl-4-hydroxyphenyl)propionate], tris-(3,5-di-t-butyl-4-hydroxybenzyl) isocyanurate, 1,3,5-trimethyl-2,4,6-tris(3,5-di-t-butyl-4-hydroxybenzyl)benzene, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-triethylmethyl-3-hydroxy-2,6-dimethylbenzyl]-1,3,5-triazine-2,4,6-(1H,3H,5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-5,6-diethyl-3-hydroxy-2-methylbenzyl)-1,3,5-triazine-2,4,6-(1H,3H,5H)-trione, 1,3,5-tris(4-t-butyl-3-hydroxy-2-methylbenzyl)-1,3,5-triazine-2,4,6-(1H,3H,5H)-trione, 1,3,5-tris(44-butyl-3-hydroxy-2,5-dimethylbenzyl)-1,3,5-triazine-2,4,6-(1H,3H,5H)-trione, and 1,3,5-tris(4-t-butyl-5-ethyl-3-hydroxy-2-methylbenzyl)-1,3,5-triazine-2,4,6-(1H,3H,5H)-trione, but the hindered phenol compound is not limited to these compounds. Of these, especially preferred is 1,3,5-tris(4-t-butyl-3-hydroxy-2,6-dimethylbenzyl)-1,3,5-triazine-2,4,6-(1H,3H,5H )-trione.

The amount of the hindered phenol compound incorporated, relative to 100 parts by mass of polyimide precursor (A), ranges preferably 0.1 to 20 parts by mass, and is more preferably 0.5 to 10 parts by mass from the viewpoint of the photosensitivity properties. When the amount of the hindered phenol compound incorporated is 0.1 part by mass or more, relative to 100 parts by mass of polyimide precursor (A), the obtained negative photosensitive resin composition, which is, for example, when applied onto copper or a copper alloy, prevents the copper or copper alloy from suffering discoloration or corrosion. On the other hand, when the amount of the hindered phenol compound incorporated is 20 parts by mass or less, the obtained negative photosensitive resin composition advantageously has excellent photosensitivity.

### Method for Producing a Cured Relief Pattern

In an embodiment, there can be provided a method for producing a cured relief pattern, which comprises the following steps (1) to (4):

(1) applying the negative photosensitive resin composition of the above embodiment onto a substrate to form a photosensitive resin layer on the substrate,

(2) subjecting the photosensitive resin layer to exposure,

(3) subjecting the exposed photosensitive resin layer to development to form a relief pattern, and

(4) subjecting the relief pattern to heating treatment to form a cured relief pattern.

The steps are individually described below.

(1) Step of applying the negative photosensitive resin composition of the above embodiment onto a substrate to form a photosensitive resin layer on the substrate

In the present step, the negative photosensitive resin composition of the above embodiment is applied onto a substrate, and, if necessary, then dried to form a photosensitive resin layer. As a method for application, a method which has conventionally been used for applying a photosensitive resin composition, for example, a coating method using a spin coater, a bar coater, a blade coater, a curtain coater, or a screen printing machine, or a spray coating method using a spray coater can be used.

If necessary, the film formed from the negative photosensitive resin composition can be dried, and, as a method for drying, for example, an air-drying, drying by heating using an oven or a hotplate, or vacuum drying method is used. Further, it is desired that drying of the film is conducted under conditions such that polyimide precursor (A) in the negative photosensitive resin composition does not undergo imidation. Specifically, when conducting air-drying or drying by heating, the drying can be conducted under conditions at 20 to 200° C. for one minute to one hour. Thus, a photosensitive resin layer can be formed on the substrate.

(2) Step of subjecting the photosensitive resin layer to exposure

In the present step, the photosensitive resin layer formed in the step (1) above is subjected to exposure through a photomask or reticle having a pattern or directly with, for example, an ultraviolet light source using an exposure apparatus, such as a contact aligner, a mirror projection, or a stepper.

Then, for the purpose of improving the photosensitivity and the like, if necessary, the resultant resin layer may be subjected to post exposure bake (PEB) and/or pre-development bake having a combination of an arbitrary temperature and time. A preferred range for the baking conditions is such that the temperature is 50 to 200° C. and the time is 10 to 600 seconds, but the baking conditions are not limited to those in the above-mentioned range as long as the properties of the negative photosensitive resin composition are not sacrificed.

(3) Step of subjecting the exposed photosensitive resin layer to development to form a relief pattern

In the present step, the unexposed portion of the exposed photosensitive resin layer is removed by development. As a development method for subjecting the exposed (irradiated) photosensitive resin layer to development, an arbitrary method can be selected from conventionally known development methods for photoresist, for example, a rotary spraying method, a paddle method, and an immersion method using an ultrasonic treatment. After the development, for example, for the purpose of adjusting the shape of the relief pattern, if necessary, the resultant relief pattern may be subjected to post development bake having a combination of an arbitrary temperature and time. As a developer used in the development, preferred is, for example, N-methyl-2-pyrrolidone, N-cyclohexyl-2-pyrrolidone, N,N-dimethylacetamide, cyclopentanone, cyclohexanone, γ-butyrolactone, or α-acetyl-γ-butyrolactone. Further, two or more types of the solvents, for example, several types of the solvents can be used in combination.

(4) Step of subjecting the relief pattern to heating treatment to form a cured relief pattern

In the present step, the relief pattern obtained in the above-mentioned development is heated to volatilize the photosensitive component and to cause polyimide precursor (A) to undergo imidation, converting the pattern to a cured relief pattern comprising a polyimide. As a heat curing method, a method can be selected from various types of methods using, for example, a hotplate, an oven, or a programed-temperature oven in which a temperature program can be set. The heating can be conducted, for example, under conditions at 130 to 250° C. for 30 minutes to 5 hours. As a gas constituting an atmosphere for the heat curing, air may be used, and an inert gas, such as nitrogen gas or argon gas, can be used.

### Semiconductor Device

In an embodiment, a semiconductor device having a cured relief pattern obtained by the above-mentioned method for producing a cured relief pattern is also provided. Accordingly, a semiconductor device having a substrate which is a semiconductor element, and a cured relief pattern of polyimide formed on the substrate by the above-mentioned method for producing a cured relief pattern can be provided. Further, the present invention can be applied to a method for producing a semiconductor device, which uses a semiconductor element as a substrate, and which comprises the above-mentioned method for producing a cured relief pattern as part of the steps. The semiconductor device of the present invention can be produced by using the above-mentioned method for producing a cured relief pattern and a known method for producing a semiconductor device in combination, wherein a cured relief pattern is formed by the above-mentioned method for producing a cured relief pattern as, for example, a surface protective film, an interlayer dielectric film, an insulating film for rewiring, a protective film for a flip chip device, or a protective film for a semiconductor device having a bump structure.

### Display Device

In an embodiment, there is provided a display device comprising a display element and a cured film formed on the upper portion of the display element, wherein the cured film is the above-mentioned cured relief pattern. In the display device, the cured relief pattern may be directly stacked on the display element, or may be stacked through another layer on the display element. Examples of the cured films include a surface protective film, an insulating film, and a planarization film for a TFT liquid crystal display element and a color filter element, a bump for an MVA liquid crystal display device, and a barrier for an organic EL element cathode.

The negative photosensitive resin composition of the present invention can be applied to a semiconductor device as mentioned above, and further can be advantageously used in applications of, for example, an interlayer dielectric film for a multilayer circuit, a cover coat for a flexible copper-clad sheet, a solder resist film, and a liquid crystal oriented film.

### EXAMPLES

Hereinbelow, the present invention will be described in more detail with reference to the following Examples, which should not be construed as limiting the scope of the present invention.

The weight average molecular weight shown in the following synthesis examples in the present specification is the result of measurement by gel permeation chromatography (hereinafter, referred to simply as “GPC” in the present specification). In the measurement, a GPC apparatus (HLC-8320GPC), manufactured by Tosoh Corp., is used, and conditions for the measurement and others are as follows.

GPC Column: KD-803, KD-805 (Shodex)

Column temperature: 50° C.

Solvent: N,N-Dimethylformamide (DMF, Kanto Chemical Co., Inc.; special grade reagent (guaranteed reagent)), lithium bromide monohydrate (Kanto Chemical Co., Inc.; Kanto special grade reagent (Cica-reagent)) (30 mM)/phosphoric acid (Aldrich) (30 mM)/tetrahydrofuran (THF, Kanto Chemical Co., Inc.; special grade reagent) (1%)

Flow rate: 1.0 mL/minute

Standard sample: Polystyrene (manufactured by GL Science Inc.)

### <Production Example 1>(Synthesis of Polymer (2B) as a Polyimide Precursor)

40.00 g (0.129 mol) of 4,4′-oxydiphthalic dianhydride (ODPA, Tokyo Chemical Industry Co., Ltd.) was placed in a four-neck flask having a capacity of 1 liter, and 29.15 g (0.227 mol) of 2-hydroxyethyl methacrylate (HEMA, Aldrich), 6.70 g (0.025 mol) of FINEOXOCOL® 180 (manufactured by Nissan Chemical Industries, Ltd.), and 116 g of γ-butyrolactone (Kanto Chemical Co., Inc.; Kanto special grade reagent) were placed in the flask, and the resultant mixture was cooled to 10° C. or lower and stirred, and 20.49 g (0.259 mol) of pyridine (Kanto Chemical Co., Inc.; dehydrated) was added to the mixture while stirring, and then the temperature of the resultant mixture was increased to 25° C., followed by stirring for 24 hours.

Then, a solution obtained by dissolving 52.15 g (0.253 mol) of N,N′-dicyclohexylcarbodiimide (DCC, Kanto Chemical Co., Inc.; Kanto special grade reagent) in 80 g of γ-butyrolactone was dropwise added to the reaction solution at 5° C. or lower over 40 minutes while stirring, and subsequently 140 g of γ-butyrolactone was added to the resultant mixture, and 44.23 g (0.120 mol) of 4,4′-bis(4-aminophenoxy)biphenyl (BAPB, Seika Corporation) was added. Then, the temperature of the resultant mixture was increased to 25° C., and 140 g of N-methyl-2-pyrrolidinone (NMP, Kanto Chemical Co., Inc.; Kanto special grade reagent) was added and the resultant mixture was stirred for 12 hours, and then 6.0 g of ethanol (Kanto Chemical Co., Inc.; special grade reagent) was added and the resultant mixture was stirred for one hour. The precipitate caused in the reaction solution was removed by filtration to obtain a reaction mixture.

The obtained reaction mixture was added to 600 g of ethanol (Kanto Chemical Co., Inc.; special grade reagent) to form a precipitate comprising a crude polymer. The precipitate was collected by filtration and dissolved in 340 g of tetrahydrofuran (THF, Kanto Chemical Co., Inc.; special grade reagent) to obtain a crude polymer solution. The obtained crude polymer solution was dropwise added to 7.2 kg of water to cause the polymer to suffer precipitation, and the resultant precipitate was collected by filtration, and then subjected to vacuum drying to obtain polymer (2B) in a fibrous form. A molecular weight of polymer 1B was measured by GPC (using a conversion calibration curve obtained from the standard polystyrene). As a result, it was found that the weight average molecular weight (Mw) was 24,181. The yield was 67.9%. The reaction product has a repeating unit structure represented by the following formula (2B).

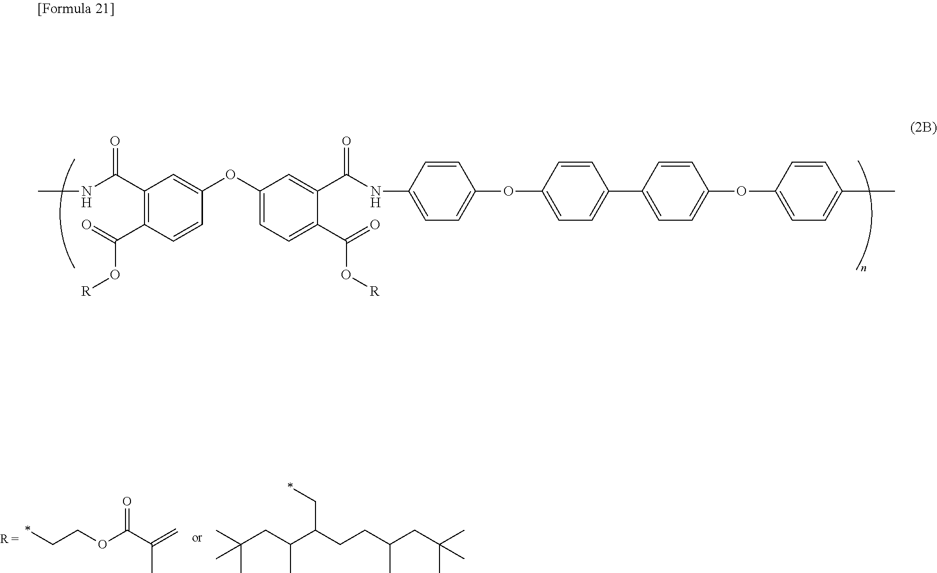

Wherein * is a site bonded to the carboxylic acid of polyimide precursor (2B).

### <Production Example 2>(Synthesis of Polymer (1B) as a Polyimide Precursor)

40.00 g (0.129 mol) of 4,4′-oxydiphthalic dianhydride (ODPA, Tokyo Chemical Industry Co., Ltd.) was placed in a four-neck flask having a capacity of 1 liter, and 16.53 g (0.129 mol) of 2-hydroxyethyl methacrylate (HEMA, Aldrich), 34.19 g (0.129 mol) of FINEOXOCOL® 180 (manufactured by Nissan Chemical Industries, Ltd.), and 116 g of γ-butyrolactone (Kanto Chemical Co., Inc.; Kanto special grade reagent) were placed in the flask, and the resultant mixture was cooled to 10° C. or lower and stirred, and 20.91 g (0.264 mol) of pyridine (Kanto Chemical Co., Inc.; dehydrated) was added to the mixture while stirring, and then the temperature of the resultant mixture was increased to 25° C., followed by stirring for 25 hours.

Then, a solution obtained by dissolving 53.21 g (0.258 mol) of N,N′-dicyclohexylcarbodiimide (DCC, Kanto Chemical Co., Inc.; Kanto special grade reagent) in 80 g of γ-butyrolactone was dropwise added to the reaction solution at 5° C. or lower over one hour while stirring, and subsequently 120 g of γ-butyrolactone was added to the resultant mixture, and 44.45 g (0.122 mol) of 4,4′-bis(4-aminophenoxy)biphenyl (BAPB, Seika Corporation) was added. Then, the temperature of the resultant mixture was increased to 25° C. and the mixture was stirred for 15 hours, and then 6.0 g of ethanol (Kanto Chemical Co., Inc.; special grade reagent) was added and the resultant mixture was stirred for one hour, and then 116 g of γ-butyrolactone was added to the mixture. The precipitate caused in the reaction solution was removed by filtration to obtain a reaction mixture.

The obtained reaction mixture was added to 600 g of ethanol (Kanto Chemical Co., Inc.; special grade reagent) to form a precipitate comprising a crude polymer. The crude polymer was separated by removing the supernatant liquid by decantation, and dissolved in 340 g of tetrahydrofuran to obtain a crude polymer solution. The obtained crude polymer solution was dropwise added to 7.2 kg of water to cause the polymer to suffer precipitation, and the resultant precipitate was collected by filtration, and then subjected to vacuum drying to obtain polymer (1B) in a fibrous form. A molecular weight of polymer 1B was measured by GPC (using a conversion calibration curve obtained from the standard polystyrene). As a result, it was found that the weight average molecular weight (Mw) was 20,112. The yield was 50.8%. The reaction product has a repeating unit structure represented by the following formula (1B).

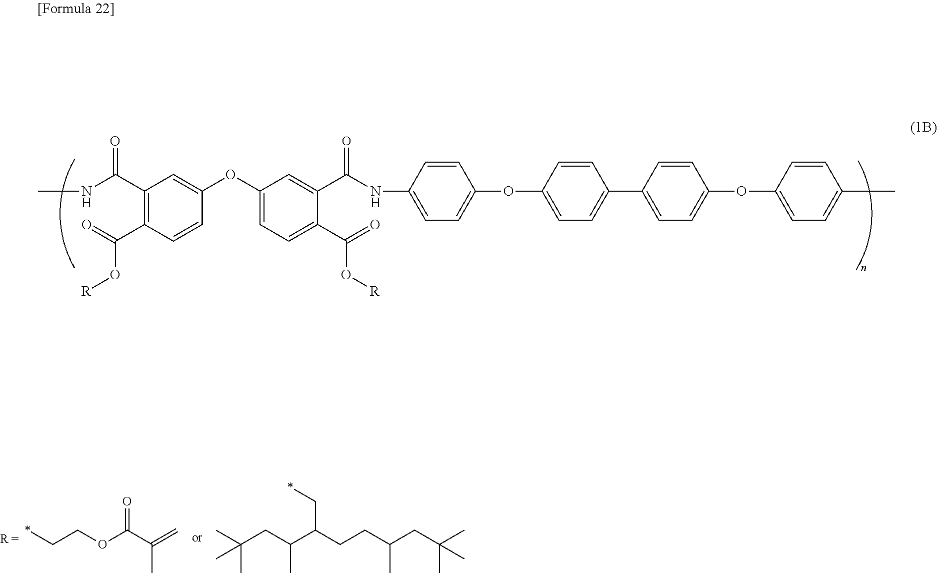

Wherein * is a site bonded to the carboxylic acid of polyimide precursor (1B).

### <Production Example 3>(Synthesis of polymer (1A) as a polyimide precursor)

40.00 g (0.129 mol) of 4,4′-oxydiphthalic dianhydride (ODPA, Tokyo Chemical Industry Co., Ltd.) was placed in a four-neck flask having a capacity of 1 liter, and 16.20 g (0.126 mol) of 2-hydroxyethyl methacrylate (HEMA, Aldrich), 20.75 g (0.126 mol) of triethylene glycol monomethyl ether (Tokyo Chemical Industry Co., Ltd.), and 116 g of γ-butyrolactone (Kanto Chemical Co., Inc.; Kanto special grade reagent) were placed in the flask, and the resultant mixture was cooled to 10° C. or lower and stirred, and 20.49 g (0.259 mol) of pyridine (Kanto Chemical Co., Inc.; dehydrated) was added to the mixture while stirring, and then the temperature of the resultant mixture was increased to 25° C., followed by stirring for 23 hours.

Then, a solution obtained by dissolving 52.15 g (0.253 mol) of N,N′-dicyclohexylcarbodiimide (DCC, Kanto Chemical Co., Inc.; Kanto special grade reagent) in 80 g of γ-butyrolactone was dropwise added to the reaction solution at 5° C. or lower over 2 hours while stirring, and subsequently a solution obtained by dissolving 42.32 g (0.116 mol) of 4,4′-bis(4-aminophenoxy)biphenyl (BAPB, Seika

Corporation) in 80 g of N-methyl-2-pyrrolidinone (NMP, Kanto Chemical Co., Inc.; Kanto special grade reagent) was dropwise added to the resultant mixture over 2 hours while stirring. Then, the temperature of the resultant mixture was increased to 25° C. and the mixture was stirred for 40 hours, and then 6.0 g of ethanol (Kanto Chemical Co., Inc.; special grade reagent) was added and the resultant mixture was stirred for one hour, and then 60 g of NMP was added to the mixture. The precipitate caused in the reaction solution was removed by filtration to obtain a reaction mixture.

140 g of tetrahydrofuran (THF, Kanto Chemical Co., Inc.; special grade reagent) was added to the obtained reaction mixture to obtain a crude polymer solution. The obtained crude polymer solution was dropwise added to 6 kg of methanol (Kanto Chemical Co., Inc.; special grade reagent) to cause the polymer to suffer precipitation, and the resultant precipitate was collected by filtration, and then subjected to vacuum drying to obtain polymer (1A) in a powdery form. A molecular weight of polymer 1A was measured by GPC (using a conversion calibration curve obtained from the standard polystyrene). As a result, it was found that the weight average molecular weight (Mw) was 20,129. The yield was 72.8%. The reaction product has a repeating unit structure represented by the following formula (1A).

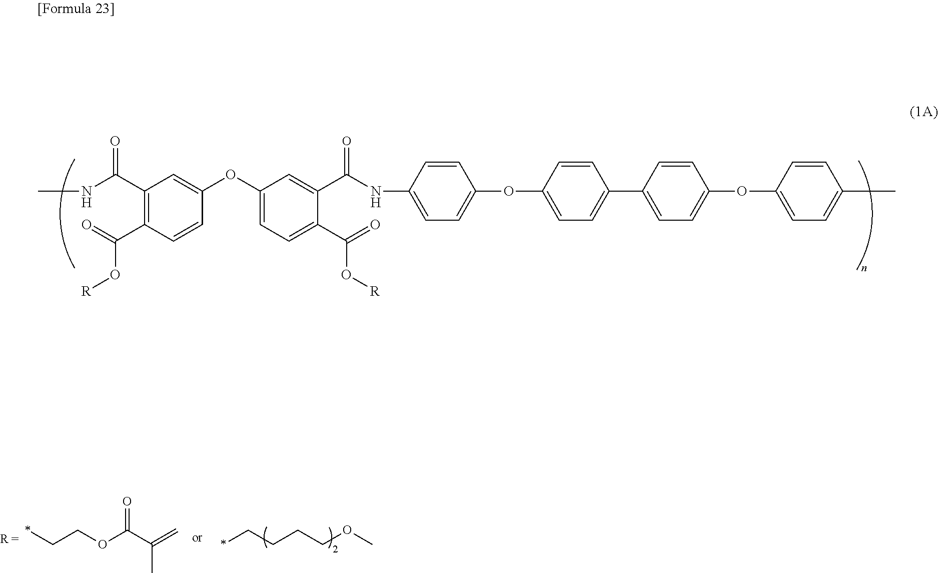

Wherein * is a site bonded to the carboxylic acid of polyimide precursor (1A).

### <Production Example 4>(Synthesis of Polymer 1C as a Polyimide Precursor)

30.00 g (0.095 mol) of 4,4′-oxydiphthalic dianhydride (ODPA) was placed in a four-neck flask having a capacity of 1 liter, and 12.15 g (0.095 mol) of 2-hydroxyethyl methacrylate (HEMA, Aldrich), 15.56 g (0.095 mol) of triethylene glycol monomethyl ether (Tokyo Chemical Industry Co., Ltd.), and 87 g of γ-butyrolactone (Kanto Chemical Co., Inc.; Kanto special grade reagent) were placed in the flask, and the resultant mixture was cooled to 10° C. or lower and stirred, and 15.37 g (0.194 mol) of pyridine (Kanto Chemical Co., Inc.; dehydrated) was added to the mixture while stirring, and then the temperature of the resultant mixture was increased to 25° C., followed by stirring for 23 hours.

Then, a solution obtained by dissolving 39.11 g (0.190 mol) of N,N′-dicyclohexylcarbodiimide (DCC, Kanto Chemical Co., Inc.; Kanto special grade reagent) in 60 g of γ-butyrolactone was dropwise added to the reaction solution at 5° C. or lower over 2 hours while stirring, and subsequently a solution obtained by dissolving 9.74 g (0.090 mol) of p-phenylenediamine (PPD) in 75 g of γ-butyrolactone was dropwise added to the resultant mixture over 2.5 hours while stirring. Then, the temperature of the resultant mixture was increased to 25° C. and the mixture was stirred for 12 hours, and then 4.52 g of ethanol (Kanto Chemical Co., Inc.; special grade reagent) was added and the resultant mixture was stirred for one hour, and then 87 g of γ-butyrolactone was added to the mixture. The precipitate caused in the reaction solution was removed by filtration to obtain a reaction mixture.

The obtained reaction mixture was added to 450 g of ethanol (Kanto Chemical Co., Inc.; special grade reagent) to form a precipitate comprising a crude polymer. The crude polymer was separated by removing the supernatant liquid by decantation, and dissolved in 255 g of tetrahydrofuran to obtain a crude polymer solution. The obtained crude polymer solution was dropwise added to 5.4 kg of water to cause the polymer to suffer precipitation, and the resultant precipitate was collected by filtration, and then subjected to vacuum drying to obtain polymer (1C) in a fibrous form. A molecular weight of polymer 1C was measured by GPC (using a conversion calibration curve obtained from the standard polystyrene). As a result, it was found that the weight average molecular weight (Mw) was 29,327. The yield was 59.9%. The reaction product has a repeating unit structure represented by the following formula (1C).

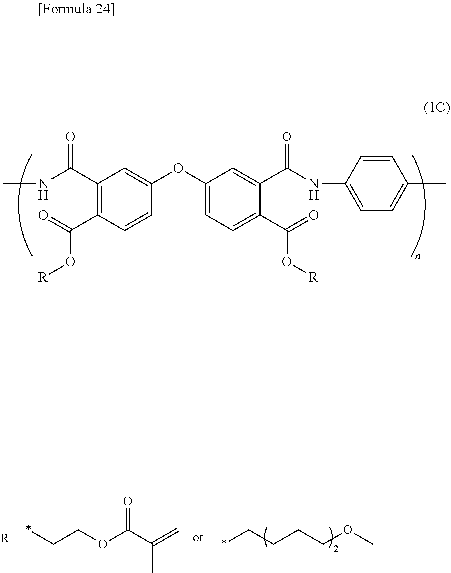

Wherein * is a site bonded to the carboxylic acid of polyimide precursor (1C).

### <Production Example 5>(Synthesis of Polymer (3B) as a Polyimide Precursor)

29.99 g (0.097 mol) of 4,4′-oxydiphthalic dianhydride (ODPA, Tokyo Chemical Industry Co., Ltd.) was placed in a four-neck flask having a capacity of 1 liter, and 23.56 g (0.184 mol) of 2-hydroxyethyl methacrylate (HEMA, Aldrich), 2.57 g (0.010 mol) of FINEOXOCOL 180 (manufactured by Nissan Chemical Industries, Ltd.), and 87 g of γ-butyrolactone (Kanto Chemical Co., Inc.; Kanto special grade reagent) were placed in the flask, and the resultant mixture was cooled to 10° C. or lower and stirred, and 15.69 g (0.198 mol) of pyridine (Kanto Chemical Co., Inc.; dehydrated) was added to the mixture while stirring, and then the temperature of the resultant mixture was increased to 25° C., followed by stirring for 23 hours.

Then, a solution obtained by dissolving 39.91 g (0.193 mol) of N,N′-dicyclohexylcarbodiimide (DCC, Kanto Chemical Co., Inc.; Kanto special grade reagent) in 60 g of γ-butyrolactone was dropwise added to the reaction solution at 5° C. or lower over 50 minutes while stirring, and subsequently 75 g of γ-butyrolactone was added to the resultant mixture, and 33.50 g (0.092 mol) of 4,4′-bis(4-aminophenoxy)biphenyl (BAPB, Seika Corporation) was added. Then, the temperature of the resultant mixture was increased to 25° C., and 90 g of N-methyl-2-pyrrolidinone (NMP, Kanto Chemical Co., Inc.; Kanto special grade reagent) was added and the resultant mixture was stirred for 15 hours, and then 4.5 g of ethanol (Kanto Chemical Co., Inc.; special grade reagent) was added and the resultant mixture was stirred for one hour. The precipitate caused in the reaction solution was removed by filtration to obtain a reaction mixture.

The obtained reaction mixture was added to 450 g of ethanol (Kanto Chemical Co., Inc.; special grade reagent) to form a precipitate comprising a crude polymer. The precipitate was collected by filtration and dissolved in 255 g of tetrahydrofuran (THF, Kanto Chemical Co., Inc.; special grade reagent) and 105 g of NMP to obtain a crude polymer solution. The obtained crude polymer solution was dropwise added to 5.4 kg of water to cause the polymer to suffer precipitation, and the resultant precipitate was collected by filtration, and then washed with 150 g of methanol (Kanto Chemical Co., Inc.; Kanto special grade reagent) twice and subjected to vacuum drying to obtain polymer (3B) in a fibrous form. A molecular weight of polymer 3B was measured by GPC (using a conversion calibration curve obtained from the standard polystyrene). As a result, it was found that the weight average molecular weight (Mw) was 26,611. The yield was 68.9%. The reaction product has a repeating unit structure represented by the following formula (3B).

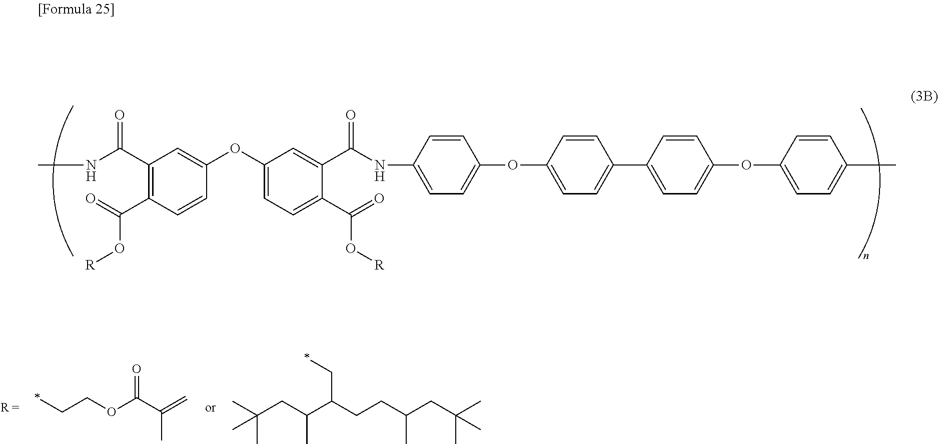

Wherein * is a site bonded to the carboxylic acid of polyimide precursor (3B).

### <Production Example 6>(Synthesis of polymer (4B) as a polyimide precursor)

30.00 g (0.097 mol) of 4,4′-oxydiphthalic dianhydride (ODPA, Tokyo Chemical Industry Co., Ltd.) was placed in a four-neck flask having a capacity of 1 liter, and 24.54 g (0.191 mol) of 2-hydroxyethyl methacrylate (HEMA, Aldrich), 0.52 g (0.002 mol) of FINEOXOCOL 180 (manufactured by Nissan Chemical Industries, Ltd.), and 87 g of γ-butyrolactone (Kanto Chemical Co., Inc.; Kanto special grade reagent) were placed in the flask, and the resultant mixture was cooled to 10° C. or lower and stirred, and 15.69 g (0.198 mol) of pyridine (Kanto Chemical Co., Inc.; dehydrated) was added to the mixture while stirring, and then the temperature of the resultant mixture was increased to 25° C., followed by stirring for 23 hours.

Then, a solution obtained by dissolving 39.90 g (0.193 mol) of N,N′-dicyclohexylcarbodiimide (DCC, Kanto Chemical Co., Inc.; Kanto special grade reagent) in 60 g of γ-butyrolactone was dropwise added to the reaction solution at 5° C. or lower over 65 minutes while stirring, and subsequently 75 g of γ-butyrolactone was added to the resultant mixture, and 33.50 g (0.092 mol) of 4,4′-bis(4-aminophenoxy)biphenyl (BAPB, Seika Corporation) was added. Then, the temperature of the resultant mixture was increased to 25° C., and 90 g of N-methyl-2-pyrrolidinone (NMP, Kanto Chemical Co., Inc.; Kanto special grade reagent) was added and the resultant mixture was stirred for 17.5 hours, and then 4.5 g of ethanol (Kanto Chemical Co., Inc.; special grade reagent) was added and the resultant mixture was stirred for one hour. The precipitate caused in the reaction solution was removed by filtration to obtain a reaction mixture.

The obtained reaction mixture was added to 450 g of ethanol (Kanto Chemical Co., Inc.; special grade reagent) to form a precipitate comprising a crude polymer. The precipitate was collected by filtration and dissolved in 360 g of tetrahydrofuran (THF, Kanto Chemical Co., Inc.; special grade reagent) and 150 g of

NMP to obtain a crude polymer solution. The obtained crude polymer solution was dropwise added to 5.4 kg of water to cause the polymer to suffer precipitation, and the resultant precipitate was collected by filtration, and then washed with 300 g of methanol twice and subjected to vacuum drying to obtain polymer (4B). A molecular weight of polymer 4B was measured by GPC (using a conversion calibration curve obtained from the standard polystyrene). As a result, it was found that the weight average molecular weight (Mw) was 26,583. The yield was 68.5%. The reaction product has a repeating unit structure represented by the following formula (4B).

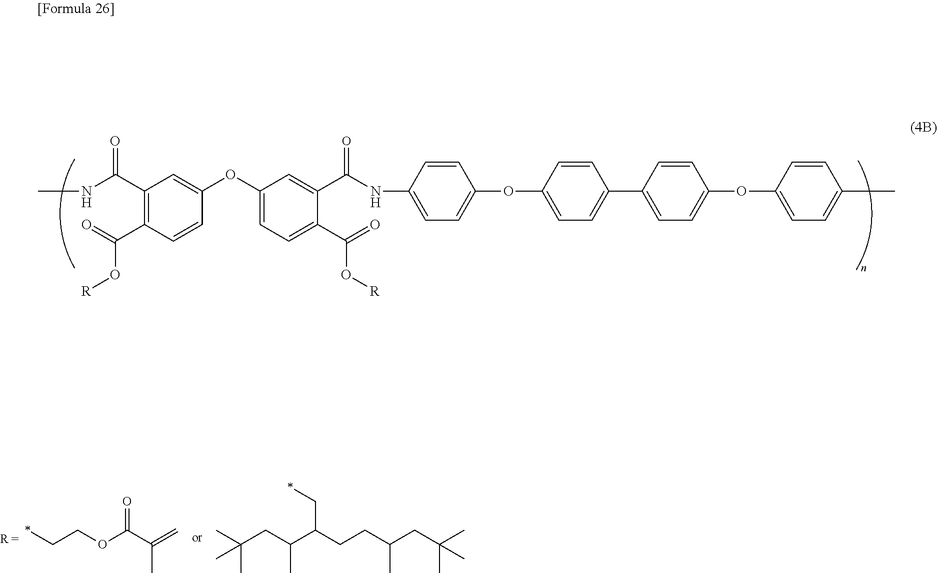

Wherein * is a site bonded to the carboxylic acid of polyimide precursor (4B).

### <Production Example 7>(Synthesis of Polymer (5B) as a Polyimide Precursor)

20.00 g (0.064 mol) of 4,4′-oxydiphthalic dianhydride (ODPA, Tokyo Chemical Industry Co., Ltd.) was placed in a four-neck flask having a capacity of 1 liter, and 8.09 g (0.063 mol) of 2-hydroxyethyl methacrylate (HEMA, Aldrich), 8.10 g (0.063 mol) of 2-ethyl-1-hexanol (manufactured by Tokyo Chemical Industry Co., Ltd.), and 58 g of γ-butyrolactone (Kanto Chemical Co., Inc.; Kanto special grade reagent) were placed in the flask, and the resultant mixture was cooled to 10° C. or lower and stirred, and 10.24 g (0.130 mol) of pyridine (Kanto Chemical Co., Inc.; dehydrated) was added to the mixture while stirring, and then the temperature of the resultant mixture was increased to 25° C., followed by stirring for 22.5 hours.

Then, a solution obtained by dissolving 26.07 g (0.126 mol) of N,N′-dicyclohexylcarbodiimide (DCC, Kanto Chemical Co., Inc.; Kanto special grade reagent) in 40 g of γ-butyrolactone was dropwise added to the reaction solution at 5° C. or lower over 60 minutes while stirring, and subsequently a solution obtained by dissolving 21.16 g (0.058 mol) of 4,4′-bis(4-aminophenoxy)biphenyl (BAPB, Seika Corporation) in 40 g of N-methyl-2-pyrrolidinone (NMP, Kanto Chemical Co., Inc.; Kanto special grade reagent) was dropwise added to the resultant mixture. Then, the temperature of the resultant mixture was increased to 25° C., and 30 g of NMP was added and the resultant mixture was stirred for 18.5 hours, and then 3.0 g of ethanol (Kanto Chemical Co., Inc.; special grade reagent) was added and the resultant mixture was stirred for one hour. The precipitate caused in the reaction solution was removed by filtration to obtain a reaction mixture.

70 g of tetrahydrofuran (THF, Kanto Chemical Co., Inc.; special grade reagent) was added to the obtained reaction mixture, and the resultant mixture was added to 3 kg of methanol (Kanto Chemical Co., Inc.; special grade reagent) to cause the polymer to suffer precipitation, and the resultant precipitate was collected by filtration, and then washed with 150 g of methanol twice and subjected to vacuum drying to obtain polymer (5B). A molecular weight of polymer 5B was measured by GPC (using a conversion calibration curve obtained from the standard polystyrene). As a result, it was found that the weight average molecular weight (Mw) was 26,279. The yield was 65.7%. The reaction product has a repeating unit structure represented by the following formula (5B).

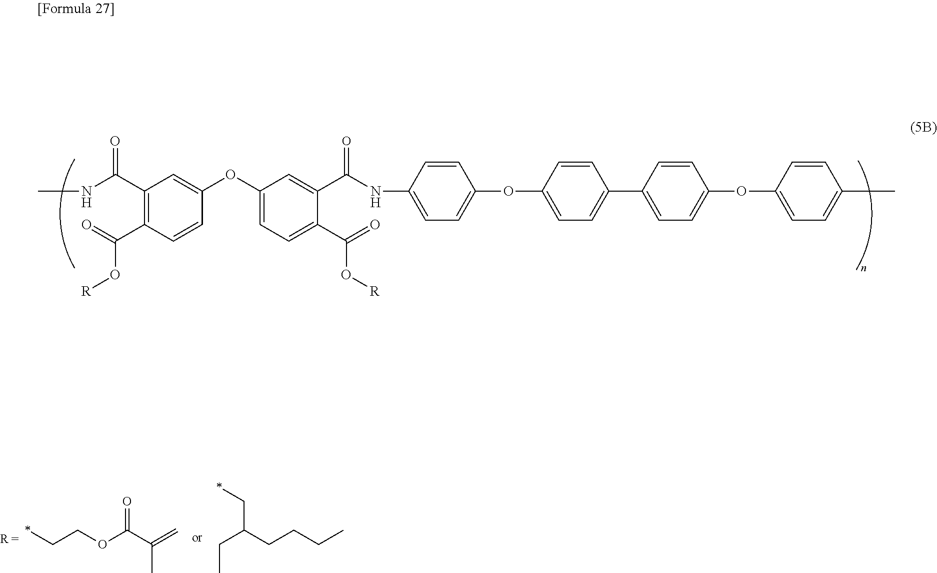

Wherein * is a site bonded to the carboxylic acid of polyimide precursor (5B).

### <Production Example 8>(Synthesis of Polymer (6B) as a Polyimide Precursor)

13.00 g (0.042 mol) of 4,4′-oxydiphthalic dianhydride (ODPA, Tokyo Chemical Industry Co., Ltd.) was placed in a four-neck flask having a capacity of 0.3 liter, and 5.37 g (0.042 mol) of 2-hydroxyethyl methacrylate (HEMA, Aldrich), 3.62 g (0.042 mol) of 3-methyl-1-butanol, and 37.7 g of γ-butyrolactone (Kanto Chemical Co., Inc.; Kanto special grade reagent) were placed in the flask, and the resultant mixture was cooled to 10° C. or lower and stirred, and 6.80 g (0.086 mol) of pyridine (Kanto Chemical Co., Inc.; dehydrated) was added to the mixture while stirring, and then the temperature of the resultant mixture was increased to 25° C., followed by stirring for 24 hours.

Then, a solution obtained by dissolving 10.58 g (0.084 mol) of N,N′-diisopropylcarbodiimide (DIC, Kanto Chemical Co., Inc.; Kanto special grade reagent) in 26.0 g of γ-butyrolactone was dropwise added to the reaction solution at 5° C. or lower over 40 minutes while stirring, and subsequently 26.0 g of γ-butyrolactone was added to the resultant mixture, and 14.52 g (0.040 mol) of 4,4′-bis(4-aminophenoxy)biphenyl (BAPB, Seika Corporation) was added. Then, the temperature of the resultant mixture was increased to 25° C., and 19.5 g of N-methyl-2-pyrrolidinone (NMP, Kanto Chemical Co., Inc.; Kanto special grade reagent) was added and the resultant mixture was stirred for 12 hours, and then 2.0 g of ethanol (Kanto Chemical Co., Inc.; special grade reagent) was added and the resultant mixture was stirred for one hour. The precipitate caused in the reaction solution was removed by filtration to obtain a reaction mixture.

The obtained reaction mixture was added to 650 g of methanol (Kanto Chemical Co., Inc.; special grade reagent) to form a precipitate comprising a crude polymer. The precipitate was collected by filtration and dissolved in 110 g of tetrahydrofuran (THF, Kanto Chemical Co., Inc.; special grade reagent) to obtain a crude polymer solution. The obtained crude polymer solution was dropwise added to 650 kg of water to cause the polymer to suffer precipitation, and the resultant precipitate was collected by filtration, and then subjected to vacuum drying to obtain polymer (6B) in a fibrous form. A molecular weight of polymer (6B) was measured by GPC (using a conversion calibration curve obtained from the standard polystyrene). As a result, it was found that the weight average molecular weight (Mw) was 14,102. The reaction product has a repeating unit structure represented by the following formula (6B).

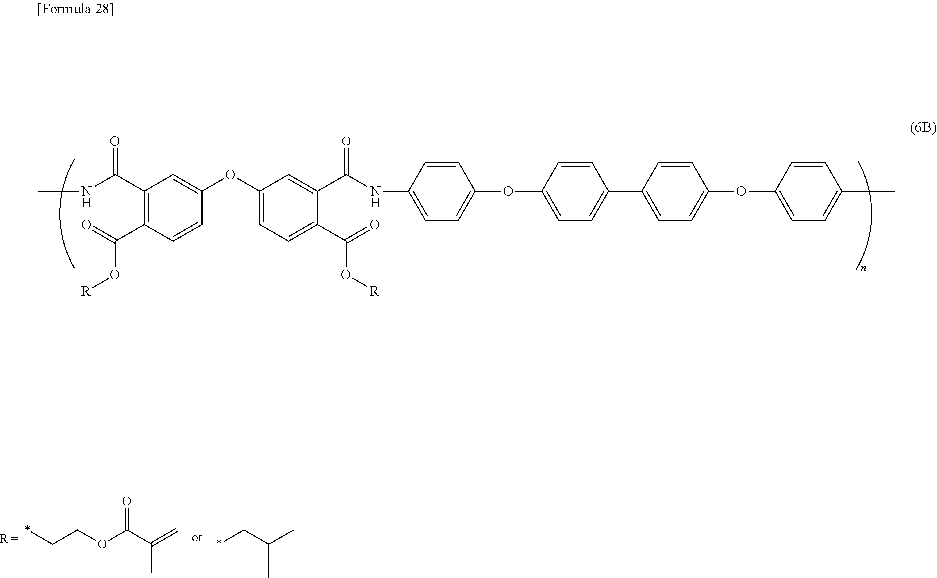

Wherein * is a site bonded to the carboxylic acid of polyimide precursor (6B).

### <Production Example 9>(Synthesis of Polymer (7B) as a Polyimide Precursor)

13.00 g (0.042 mol) of 4,4′-oxydiphthalic dianhydride (ODPA, Tokyo Chemical Industry Co., Ltd.) was placed in a four-neck flask having a capacity of 0.3 liter, and 5.37 g (0.042 mol) of 2-hydroxyethyl methacrylate (HEMA, Aldrich), 1.89 g (0.042 mol) of ethanol, and 37.7 g of γ-butyrolactone (Kanto Chemical Co., Inc.; Kanto special grade reagent) were placed in the flask, and the resultant mixture was cooled to 10° C. or lower and stirred, and 6.80 g (0.086 mol) of pyridine (Kanto Chemical Co., Inc.; dehydrated) was added to the mixture while stirring, and then the temperature of the resultant mixture was increased to 25° C., followed by stirring for 24 hours.

Then, a solution obtained by dissolving 10.58 g (0.084 mol) of N,N′-diisopropylcarbodiimide (DIC, Kanto Chemical Co., Inc.; Kanto special grade reagent) in 26.0 g of γ-butyrolactone was dropwise added to the reaction solution at 5° C. or lower over 40 minutes while stirring, and subsequently 26.0 g of γ-butyrolactone was added to the resultant mixture, and 14.52 g (0.040 mol) of 4,4′-bis(4-aminophenoxy)biphenyl (BAPB, Seika Corporation) was added. Then, the temperature of the resultant mixture was increased to 25° C., and 19.5 g of N-methyl-2-pyrrolidinone (NMP, Kanto Chemical Co., Inc.; Kanto special grade reagent) was added and the resultant mixture was stirred for 12 hours, and then 2.0 g of ethanol (Kanto Chemical Co., Inc.; special grade reagent) was added and the resultant mixture was stirred for one hour. The precipitate caused in the reaction solution was removed by filtration to obtain a reaction mixture.

The obtained reaction mixture was added to 650 g of methanol (Kanto Chemical Co., Inc.; special grade reagent) to form a precipitate comprising a crude polymer. The precipitate was collected by filtration and dissolved in 110 g of tetrahydrofuran (THF, Kanto Chemical Co., Inc.; special grade reagent) to obtain a crude polymer solution. The obtained crude polymer solution was dropwise added to 650 kg of water to cause the polymer to suffer precipitation, and the resultant precipitate was collected by filtration, and then subjected to vacuum drying to obtain polymer (7B) in a fibrous form. A molecular weight of polymer (7B) was measured by GPC (using a conversion calibration curve obtained from the standard polystyrene). As a result, it was found that the weight average molecular weight (Mw) was 12,401. The reaction product has a repeating unit structure represented by the following formula (7B).

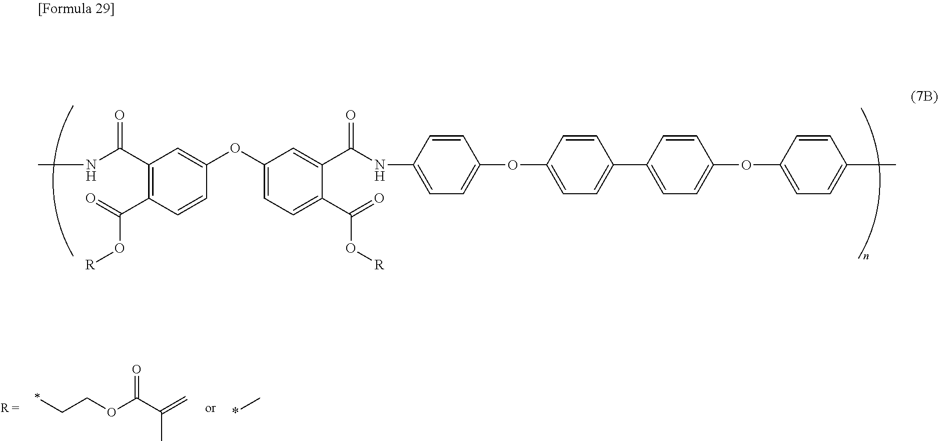

Wherein * is a site bonded to the carboxylic acid of polyimide precursor (7B).

### Example 1

8.00 g of the polymer obtained in Production Example 1, 0.16 g of

IRGACURE® OXE01 (manufactured by BASF AG), 0.80 g of tricyclodecanedimethanol diacrylate (manufactured by Shin-Nakamura Chemical Co., Ltd.), and 0.80 g of NEW FRONTIER® HBPE-4 (manufactured by Dai-ich Kogyo Seiyaku Co., Ltd.) were dissolved in 27.78 g of cyclohexanone to prepare a composition. Then, the composition was subjected to filtration using a polypropylene microfilter having a pore diameter of 5 μm to prepare a negative photosensitive resin composition.

### Example 2

11.40 g of the polymer obtained in Production Example 2, 0.23 g of IRGACURE® OXE01 (manufactured by BASF AG), 1.14 g of tricyclodecanedimethanol diacrylate (manufactured by Shin-Nakamura Chemical Co., Ltd.), and 1.14 g of NEW FRONTIER® HBPE-4 (manufactured by Dai-ich Kogyo Seiyaku Co., Ltd.) were dissolved in 28.23 g of cyclohexanone to prepare a composition. Then, the composition was subjected to filtration using a polypropylene microfilter having a pore diameter of 5 μm to prepare a negative photosensitive resin composition.

### Example 3

11.00 g of the polymer obtained in Production Example 5, 0.22 g of IRGACURE® OXE01 (manufactured by BASF AG), 1.10 g of tricyclodecanedimethanol diacrylate (manufactured by Shin-Nakamura Chemical Co., Ltd.), and 1.10 g of NEW FRONTIER® HBPE-4 (manufactured by Dai-ich Kogyo Seiyaku Co., Ltd.) were dissolved in 24.92 g of cyclohexanone to prepare a composition. Then, the composition was subjected to filtration using a polypropylene microfilter having a pore diameter of 5 μm to prepare a negative photosensitive insulating film composition.

### Example 4

9.00 g of the polymer obtained in Production Example 6, 0.18 g of IRGACURE® OXE01 (manufactured by BASF AG), 0.90 g of tricyclodecanedimethanol diacrylate (manufactured by Shin-Nakamura Chemical Co., Ltd.), and 0.90 g of NEW FRONTIER® HBPE-4 (manufactured by Dai-ich Kogyo

Seiyaku Co., Ltd.) were dissolved in 20.39 g of cyclohexanone to prepare a composition. Then, the composition was subjected to filtration using a polypropylene microfilter having a pore diameter of 5 μm to prepare a negative photosensitive insulating film composition.

### Example 5

9.00 g of the polymer obtained in Production Example 7, 0.18 g of IRGACURE® OXE01 (manufactured by BASF AG), 0.90 g of tricyclodecanedimethanol diacrylate (manufactured by Shin-Nakamura Chemical Co., Ltd.), and 0.90 g of NEW FRONTIER® HBPE-4 (manufactured by Dai-ich Kogyo Seiyaku Co., Ltd.) were dissolved in 20.39 g of cyclohexanone to prepare a composition. Then, the composition was subjected to filtration using a polypropylene microfilter having a pore diameter of 5 μm to prepare a negative photosensitive insulating film composition.

### Comparative Example 1

9.00 g of the polymer obtained in Production Example 3, 0.18 g of IRGACURE® OXE01 (manufactured by BASF AG), 0.90 g of tricyclodecanedimethanol diacrylate (manufactured by Shin-Nakamura Chemical Co., Ltd.), and 0.90 g of NEW FRONTIER® HBPE-4 (manufactured by Dai-ich Kogyo Seiyaku Co., Ltd.) were dissolved in 19.52 g of N-methyl-2-pyrrolidone to prepare a composition. Then, the composition was subjected to filtration using a polypropylene microfilter having a pore diameter of 5 μm to prepare a negative photosensitive resin composition.

### Comparative Example 2

9.00 g of the polymer obtained in Production Example 4, 0.18 g of IRGACURE® OXE01 (manufactured by BASF AG), 0.90 g of tricyclodecanedimethanol diacrylate (manufactured by Shin-Nakamura Chemical Co., Ltd.), and 0.90 g of NEW FRONTIER® HBPE-4 (manufactured by Dai-ich Kogyo Seiyaku Co., Ltd.) were dissolved in 19.52 g of N-methyl-2-pyrrolidone to prepare a composition. Then, the composition was subjected to filtration using a polypropylene microfilter having a pore diameter of 5 μm to prepare a negative photosensitive resin composition.

### Reference Example 1

9.00 g of the polymer obtained in Production Example 8, 0.18 g of IRGACURE® OXE01 (manufactured by BASF AG), 0.90 g of tricyclodecanedimethanol diacrylate (manufactured by Shin-Nakamura Chemical Co., Ltd.), and 0.90 g of NEW FRONTIER® HBPE-4 (manufactured by Dai-ich Kogyo

Seiyaku Co., Ltd.) were dissolved in 19.52 g of N-methyl-2-pyrrolidone to prepare a composition. Then, the composition was subjected to filtration using a polypropylene microfilter having a pore diameter of 5 pm to prepare a negative photosensitive resin composition.

### Reference Example 2

9.00 g of the polymer obtained in Production Example 9, 0.18 g of IRGACURE® OXE01 (manufactured by BASF AG), 0.90 g of tricyclodecanedimethanol diacrylate (manufactured by Shin-Nakamura Chemical Co., Ltd.), and 0.90 g of NEW FRONTIER® HBPE-4 (manufactured by Dai-ich Kogyo Seiyaku Co., Ltd.) were dissolved in 19.52 g of N-methyl-2-pyrrolidone to prepare a composition. Then, the composition was subjected to filtration using a polypropylene microfilter having a pore diameter of 5μm to prepare a negative photosensitive resin composition.

### Test for Electrical Properties

The negative photosensitive resin compositions prepared in Examples 1 to 5, Comparative Examples 1 and 2, and Reference Examples 1 and 2 were individually applied using a spin coater onto a silicon wafer having aluminum stacked thereon, and prebaked at 100° C., and subjected to exposure (i-line; exposed dose: 500 mJ/cm²) using an aligner (PLA-501, manufactured by Canon Inc.), and further baked at 100° C., and then further baked at 160° C. to form a film having a thickness of 10 μm. Then, the film was immersed in 6 N hydrochloric acid. At a point in time when aluminum was dissolved and the film rose, the film was recovered, and cut into a size having a length of 3 cm and a width of 9 cm to obtain a self-supporting film. Using the obtained self-supporting film, a relative permittivity and a dielectric loss tangent at 1 GHz were determined by a cavity resonator method of a perturbation method type (apparatus: TMR-1A, manufactured by Keycom Corp.). The details of the method for measurement are as follows.

### Method for Measurement

Cavity resonator method of a perturbation method type

### Constituents of the Apparatus

Vector network analyzer: FieldFox N9926A (manufactured by Keysight Technologies, Inc.)

Cavity resonator: Model TMR-1A (manufactured by Keycom Corp.)

Cavity capacity: 1192822 mm̂3

Frequency for measurement: About 1 GHz (which depends on the resonance frequency of a sample)

Sample tube: made of PTFE; inner diameter: 3 mm; length: about 30 mm

The results of the evaluation are shown in Table 1 below. With respect to Comparative Example 2, the film to be evaluated was so brittle that the film could not be evaluated in respect of the electrical properties.

TABLE 1

| | Relative | Dielectric |
|---|---|---|
| | permittivity | loss tangent |
| Example 1 | 3.0 | 0.018 |
| Example 2 | 3.1 | 0.013 |
| Example 3 | 3.1 | 0.017 |
| Example 4 | 3.2 | 0.015 |
| Example 5 | 3.1 | 0.012 |
| Comparative | 3.5 | 0.024 |
| Example 1 | | |
| Comparative | Not | Not |
| Example 2 | evaluated | evaluated |
| Reference | 3.3 | 0.021 |
| Example 1 | | |
| Reference | 3.3 | 0.021 |
| Example 2 | | |

### INDUSTIRAL APPLICABILITY

The negative photosensitive resin composition of the present invention can be advantageously used in the field of photosensitive materials which are useful in producing electric and electronic materials for, for example, a semiconductor device and a multilayer circuit board.

1. A negative photosensitive resin composition comprising:
100 parts by mass of (A) a polyimide precursor having a unit structure represented by the following general formula (1): 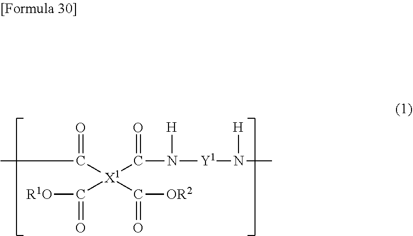
wherein X¹ is a tetravalent organic group having 6 to 40 carbon atoms, Y¹ is a divalent organic group having 6 to 40 carbon atoms, and each of R¹ and R² is independently a hydrogen atom or a monovalent organic group selected from the following general formulae (2) and (3): 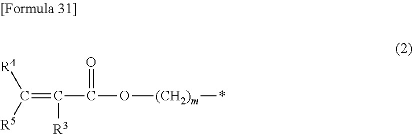
wherein each of R³, R⁴, and R⁵ is independently a hydrogen atom or a monovalent organic group having 1 to 3 carbon atoms, m is an integer of 1 to 10, and * is a site bonded to a carboxylic acid present in a polyamic acid main chain of the general formula (1),
[Formula 32]
R⁶—* (3)
wherein R⁶ is a monovalent organic group selected from alkyl groups having 1 to 30 carbon atoms, and * is as defined above,
and a proportion of a total amount of the monovalent organic group represented by the general formula (2) above and the monovalent organic group represented by the general formula (3) above in a total amount of R¹ and R² is 80 mol % or more,
and a proportion of an amount of the monovalent organic group represented by the general formula (3) above in a total amount of R¹ and R² is 1 to 90 mol%; and
0.1 to 20 parts by mass of (B) a radical photopolymerization initiator.

2. The negative photosensitive resin composition according to claim 1, wherein R⁶ is represented by the following formula (4): 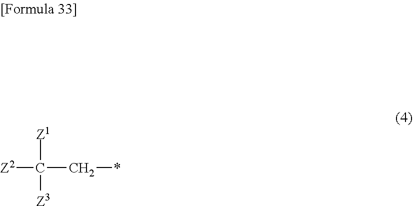
wherein Z¹ is hydrogen or an alkyl group having 1 to 14 carbon atoms,
Z² is an alkyl group having 1 to 14 carbon atoms, and
Z³ is an alkyl group having 1 to 14 carbon atoms,
wherein Z¹, Z², and Z³ may be the same or different from each other, with the proviso that the total number of carbon atoms of Z¹, Z², and Z³ is 4 or more.

3. The negative photosensitive resin composition according to claim 1, wherein R⁶ is selected from the following formulae (3-1) to (3-7): 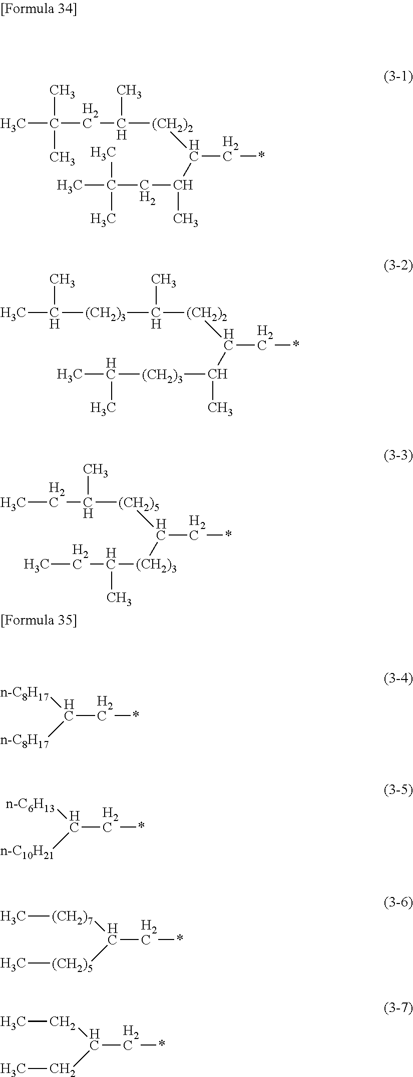
wherein * is as defined above.

4. The negative photosensitive resin composition according to claim 1, further comprising 0.1 to 30 parts by mass of (C) a crosslinkable compound, relative to 100 parts by mass of the polyimide precursor (A).

5. A negative photosensitive resin film which is a baked material of an applied film comprising the negative photosensitive resin composition according to claim 1.

6. A method for producing a cured relief pattern, comprising the steps of:
(1) applying the negative photosensitive resin composition according to claim 1 onto a substrate to form a photosensitive resin layer on the substrate,
(2) subjecting the photosensitive resin layer to exposure,
(3) subjecting the exposed photosensitive resin layer to development to form a relief pattern, and
(4) subjecting the relief pattern to heating treatment to form a cured relief pattern.

7. A cured relief pattern produced by the method according to claim 6.

8. A semiconductor device comprising a semiconductor element, and a cured film formed on the upper portion or lower portion of the semiconductor element, wherein the cured film is the cured relief pattern according to claim 6.
